(19) United States
(12) Patent Application Publication
(10) Pub. No.: US 2024/0431122 A1
(43) Pub. Date: Dec. 26, 2024

(54) SEMICONDUCTOR DEVICE

(71) Applicant: SAMSUNG ELECTRONICS CO., LTD., Suwon-si (KR)

(72) Inventors: Hongjun LEE, Suwon-si (KR); Kiseok LEE, Suwon-si (KR); Hyungeun CHOI, Suwon-si (KR); Keunnam KIM, Suwon-si (KR); Incheol NAM, Suwon-si (KR)

(73) Assignee: SAMSUNG ELECTRONICS CO., LTD., Suwon-si (KR)

(21) Appl. No.: 18/623,732

(22) Filed: Apr. 1, 2024

(30) Foreign Application Priority Data
Jun. 21, 2023 (KR) 10-2023-0079953

(51) Int. Cl. H10B 80/00; G11C 11/4091; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; G11C 11/4091; H01L 2224/08145; H01L 2224/80895; H01L 2224/80896; H01L 2924/1431; H01L 2924/1436

(57) ABSTRACT

A semiconductor device includes a lower chip structure, and an upper chip structure on the lower chip structure. The lower chip structure includes a memory structure, a lower interconnection structure electrically connected to the memory structure, and a lower bonding pad electrically connected to the lower interconnection structure. The upper chip structure includes an upper base, a peripheral transistor on the upper base, a first upper interconnection structure electrically connected to the peripheral transistor, on the upper base, a through-via penetrating through the upper base and electrically connected to the first upper interconnection structure, an upper bonding pad bonded to the lower bonding pad, below the upper base, and an intermediate connection structure electrically connecting the upper bonding pad and the through-via, between the upper base and the lower chip.

### CROSS-REFERENCE TO RELATED APPLICATION

This application claims priority to Korean Patent Application No. 10-2023-0079953, filed on Jun. 21, 2023, in the Korean Intellectual Property Office, the disclosure of which is incorporated by reference herein in its entirety.

### BACKGROUND

The present disclosure relates to a semiconductor device and a method of manufacturing the same.

Research is being conducted to reduce the size of elements constituting semiconductor devices and to improve performance thereof. For example, research is being conducted to reliably and stably form reduced-size elements in a dynamic random access memory (DRAM).

### SUMMARY

Example embodiments provide a semiconductor device in which a degree of integration may be improved.

According to an aspect of an example embodiment, a semiconductor device includes: a lower chip structure; and an upper chip structure on the lower chip structure, wherein the lower chip structure includes: a memory structure; a lower interconnection structure electrically connected to the memory structure; and a lower bonding pad electrically connected to the lower interconnection structure, and wherein the upper chip structure includes: an upper base; a peripheral transistor on the upper base; a first upper interconnection structure on the upper base and electrically connected to the peripheral transistor; a through-via penetrating through the upper base and electrically connected to the first upper interconnection structure; an upper bonding pad below the upper base and bonded to the lower bonding pad; and an intermediate connection structure between the upper base and the lower chip structure and electrically connecting the upper bonding pad and the through-via.

According to an aspect of an example embodiment, a semiconductor device includes: a lower chip structure including: a first memory area; a second memory area; and an extension area between the first memory area and the second memory area; and an upper chip structure on the lower chip structure, wherein the lower chip structure further includes: bit lines in the first memory area and extending into the extension area; and complementary bit lines in the second memory area and extending into the extension area, wherein the upper chip includes: an upper base; a sense amplifier array region including sense amplifier regions on the upper base; and through-vias penetrating through the upper base, wherein the sense amplifier array region vertically overlaps the first memory area, wherein a first sense amplifier region, from among the sense amplifier regions, is electrically connected to a first bit line of the bit lines and to a first complementary bit line from among the complementary bit lines, wherein the first sense amplifier region includes: a first connection region; a second connection region; and a first sense amplifier, and wherein the through-vias include: a first routing through-via below the first connection region and penetrating through the upper base; and a second routing through-via below the second connection region and penetrating through the upper base.

According to an aspect of an example embodiment, a semiconductor device includes: a lower chip structure including: a first memory area; a second memory area; and an extension area between the first memory area and the second memory area; and an upper chip structure on the lower chip structure, wherein the lower chip structure includes: bit lines in the first memory area and extending into the extension area; complementary bit lines in the second memory area and extending into the extension area; a lower routing bonding pad array region on the first memory area, and including first lower routing bonding pads and second lower routing bonding pads; first lower routing interconnection structures electrically connecting the bit lines and the first lower routing bonding pads; and second lower routing interconnection structures electrically connecting the complementary bit lines and the second lower routing bonding pads, wherein the upper chip structure includes: an upper base; a sense amplifier array region on the upper base and including sense amplifier regions; an upper routing bonding pad array region below the upper base, and including first upper routing bonding pads and second upper routing bonding pads; routing through-vias penetrating through the upper base, and including first routing through-vias and second routing through-vias; first intermediate routing connection structures between the upper base and the upper routing bonding pad array region, and electrically connecting the first routing through-vias and the first upper routing bonding pads; and second intermediate routing connection structures between the upper base and the upper routing bonding pad array region, and electrically connecting the second routing through-vias and the second upper routing bonding pads, wherein the first lower routing bonding pads and the second lower routing bonding pads are bonded to the first upper routing bonding pads and the second upper routing bonding pads, wherein the sense amplifier array region, the routing through-vias, the upper routing bonding pad array region, and the lower routing bonding pad array region overlap the first memory area vertically, and wherein a first sense amplifier region, from among the sense amplifier regions, is electrically connected to a first bit line, from among the bit lines, and a first upper bit line, from among the complementary bit lines.

### BRIEF DESCRIPTION OF THE DRAWINGS

The above and other aspects, features, and advantages will be more apparent from the following detailed description of example embodiments, taken in conjunction with the accompanying drawings, in which:

FIGS. 1A, 1B, 2, 3, 4, 5A, 5B, 5C, 5d, 6, 7A, 7B, 8 and 9 are views illustrating a semiconductor device according to one or more example embodiments;

FIG. 10 is a cross-sectional view illustrating a modified example of a semiconductor device according to one or more example embodiments;

FIG. 11 is a plan view illustrating a modified example of a semiconductor device according to one or more example embodiments;

FIG. 12 is a plan view illustrating a modified example of a semiconductor device according to one or more example embodiments;

FIG. 13 is a plan view illustrating a modified example of a semiconductor device according to one or more example embodiments;

FIG. 14 is a plan view illustrating a modified example of a semiconductor device according to one or more example embodiments;

FIG. 15 is a plan view illustrating a modified example of a semiconductor device according to one or more example embodiments;

FIG. 16 is a cross-sectional view illustrating a modified example of a semiconductor device according to one or more example embodiments;

FIG. 17 is a cross-sectional view illustrating a modified example of a semiconductor device according to one or more example embodiments;

FIG. 18 is a cross-sectional view illustrating a modified example of a semiconductor device according to one or more example embodiments;

FIG. 19 is a cross-sectional view illustrating a modified example of a semiconductor device according to one or more example embodiments;

FIGS. 20A and 20B are diagrams illustrating modified examples of a semiconductor device according to one or more example embodiments;

FIG. 21 is a cross-sectional view illustrating a modified example of a semiconductor device according to one or more example embodiments;

FIGS. 22 and 23 are diagrams illustrating an example of a memory structure of a semiconductor device according to one or more example embodiments; and

FIGS. 24, 25A, 25B, 26A, 26B, 27A, 27B, 28A and 28B are diagrams illustrating illustrative examples of a method of manufacturing a semiconductor device according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

Hereinafter, terms such as “upper”, “intermediate, “middle”, “lower” and the like, may be replaced with other terms, such as “first”, “second”, “third” and the like, to describe the elements of one or more example embodiments. Terms such as “first”, “second” and “third” may be used to describe various elements of one or more example embodiments, but the elements are not limited by the terms, and a “first element” may be referred to as a “second element.” Also, in example embodiments, terms such as “lower surface,” “upper surface,” “uppermost,” and “lowermost” may be terms described based on drawings.

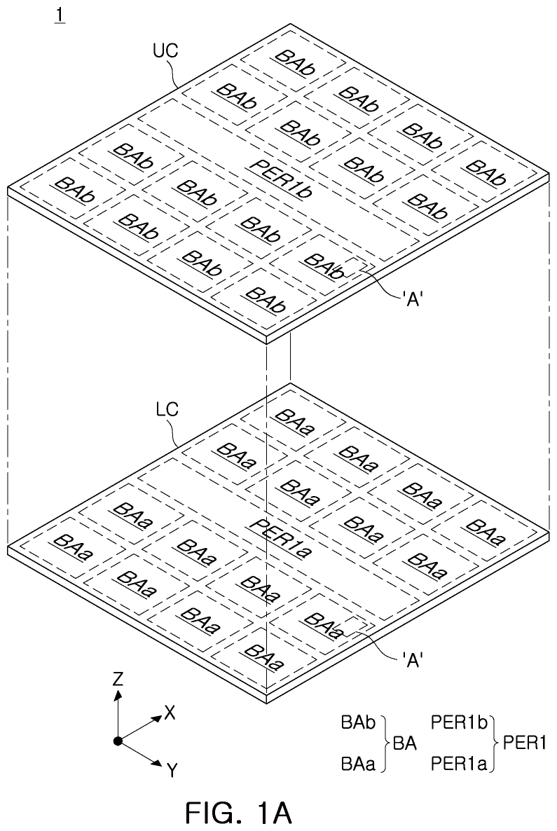

FIG. 1A is a schematic perspective view of a semiconductor device according to one or more example embodiments, and FIG. 1B is a plan view schematically illustrating a portion of a bank BA of FIG. 1A.

Referring to FIGS. 1A and 1, a semiconductor device 1 according to one or more example embodiments may include a lower chip structure LC and an upper chip structure UC provided on the lower chip structure LC. The lower chip structure LC and the upper chip structure UC may be sequentially stacked in the vertical direction Z.

The semiconductor device 1 may include a plurality of banks BA and a first peripheral area PER1. Each of the plurality of banks BA may include a lower region BAa in the lower chip structure LC and an upper region BAb in the upper chip structure UC.

The first peripheral area PER1 may include a first lower region PER1a in the lower chip structure LC and a first upper region PER1b in the upper chip structure UC. The first peripheral area PER1 may be a peripheral circuit area in which peripheral circuits for input/output of data or commands or input of power/ground are provided.

Each of the banks BA may include memory areas CR, extension areas EXTb and EXTw adjacent to the memory areas CR, and peripheral circuit areas PC vertically overlapping the memory areas CR. The memory areas CR and the extension areas EXTb and EXTw may be provided in the lower regions BAa of the banks BA of the lower chip structure LC, and the peripheral circuit area PCs may be provided in the upper regions BAb of the banks BA of the upper chip structure UC.

Each of the memory areas CR includes cell switching elements including gate electrodes, bit lines electrically connected to the cell switching elements, and data storage structures electrically connected to the cell switching elements. The gate electrodes of the cell switching elements may be word lines.

The extension areas EXTb and EXTw may include an extension area EXTb adjacent to the memory areas CR in a first direction X and an extension area EXTw adjacent to the memory areas CR in a second direction Y The extension area EXTb adjacent to the memory areas CR in the first direction X may be a bit line extension area in which bit lines in the memory areas CR extend, and the extension area EXTw adjacent to the memory areas CR in the second direction Y may be a word line extension area in which word lines in the memory areas CR extend.

In one or more example embodiments, the first direction X and the second direction Y may be perpendicular to each other. The first direction X and the second direction Y may be perpendicular to the vertical direction Z.

The memory areas CR may include a first memory area CR1, and a second memory area CR2 adjacent to the first memory area CR1 and spaced apart from the first memory area CR1 by the extension area EXTb.

Each of the peripheral circuit areas PC may include a sense amplifier array region (SAR), a subword line driver area (SWDR), and a second peripheral area PER2 between the sense amplifier array region SAR and the subword line driver area SWDR.

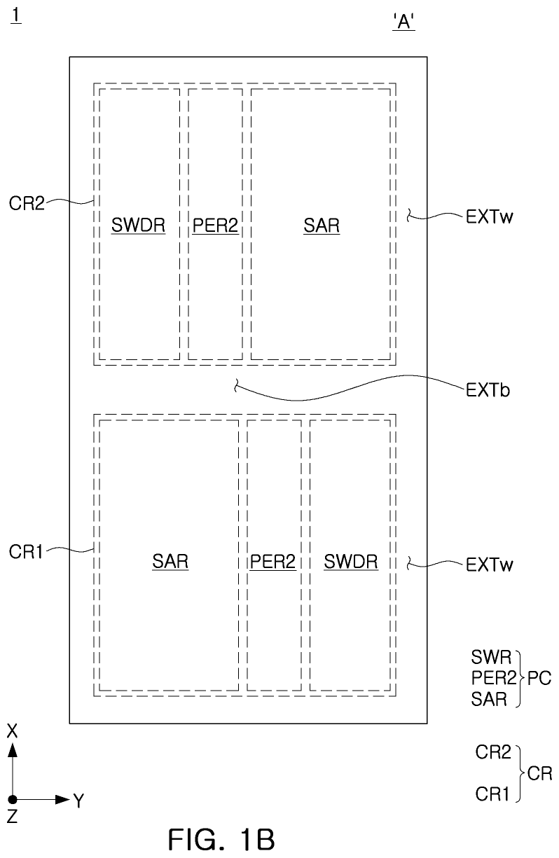

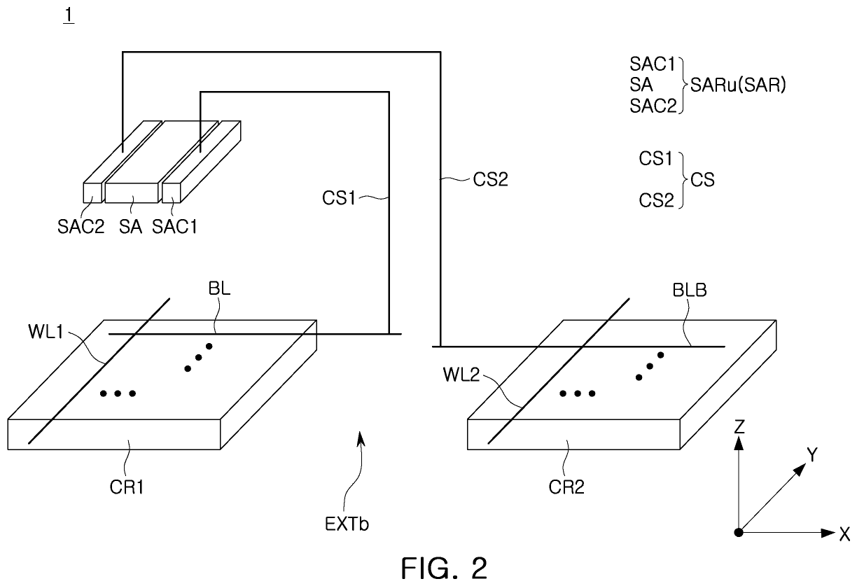

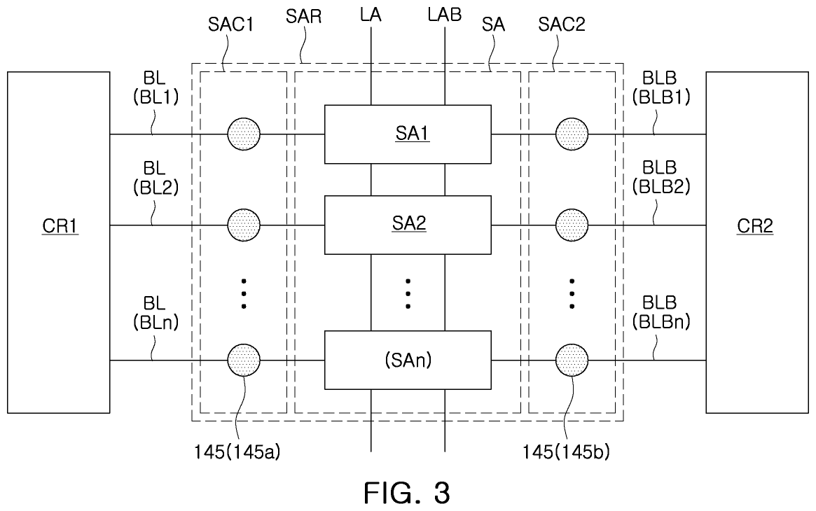

Referring to FIGS. 2, 3 and 4, together with FIGS. 1A and 1, an electrical connection relationship between the first and second memory areas CR1 and CR2 included in the lower chip structure LC and the sense amplifier array region SAR included in the upper chip structure UC will be described. FIG. 2 is a three-dimensional conceptual perspective view illustrating electrical connections of semiconductor devices according to one or more example embodiments. FIG. 3 is a conceptual block diagram illustrating electrical connection relationship between the first and second memory areas CR1 and CR2 and the sense amplifier array region SAR included in the upper chip structure UC, in a semiconductor device according to one or more example embodiments. FIG. 4 is a diagram including a circuit of the sense amplifier SA of FIGS. 2 and 3 according to one or more example embodiments, and is a drawing illustrating the electrical connection relationship between one first sense amplifier SA1 among the sense amplifiers SA, one first bit line BL1 electrically connected to the first sense amplifier SA1 among the plurality of bit lines BL, and one first complementary bit line BLB1 electrically connected to the first sense amplifier SA1 among the plurality of complementary bit lines BLB.

Referring to FIG. 2, together with FIGS. 1A and 1B, the first memory area CR1 may include a first memory structure including a bit line BL and a word line WL. The bit line BL may extend in a first direction X, and the word line WL1 may extend in a second direction Y perpendicular to the first direction X.

The second memory area CR2 may include a second memory structure including a bit line BLB and a word line WL2. The bit line BLB may extend in the first direction X, and the word line WL2 may extend in the second direction Y.

In the semiconductor device 1, when the first memory area CR1 is a normal memory area and the second memory area CR2 is a reference memory area, the bit line BL of the first memory area CR1 may be a bit line for sensing data stored in a data storage structure in the first memory area CR1, and the bit line BLB of the second memory area CR2 may be a complementary bit line.

Hereinafter, the bit line BL of the first memory area CR is referred to as a ‘bit line,’ and the bit line BLB of the second memory area CR2 will be referred to as a complementary bit line for description.

The sense amplifier array region SAR may include a plurality of unit sense amplifier regions SARu. Each of the unit sense amplifier regions SARu may include a first connection region SAC1, a second connection region SAC2, and a sense amplifier SA between the first connection region SAC1 and the second connection region SAC2.

The semiconductor device 1 may include routing structures (CS) electrically connecting the bit line BL of the first memory area CR1, the complementary bit line BLB of the second memory area CR2 and the unit sense amplifier region (SARu).

The routing structures (CS) may include a first routing structure CS1 electrically connecting the bit line BL of the first memory area CR1 and the first connection region SAC1, and a second routing structure CS2 electrically connecting the complementary bit line BLB of the second memory area CR2 and the second connection region SAC2.

The bit line BL of the first memory area CR1 may be provided as a plurality of bit lines BL. The bit lines BL may be spaced apart from each other in the second direction Y The complementary bit line BLB of the second memory area CR2 may be provided as a plurality of the complementary bit lines. The complementary bit lines BLB may be spaced apart from each other in the second direction Y.

The bit lines BL of the first memory area CR1 may extend into the extension area EXTb and may be electrically connected to the first routing structures CS1. The complementary bit lines BLB of the second memory area CR2 may extend into the extension area EXTb and may be electrically connected to the second routing structures CS2.

The first memory area CR1 and the second memory area CR2 may be electrically connected to the sense amplifier array region SAR. The bit lines BL of the first memory area CR1 may include n bit lines BL1, BL2, . . . , BLn. The complementary bit lines BLB of the second memory area CR2 may include n complementary bit lines BLB1, BLB2, . . . , BLBn. The sense amplifiers SA of the sense amplifier array region SAR may include n sense amplifiers SA1, SA2, . . . , SAn. One sense amplifier SA1 among the sense amplifiers SA1, SA2, . . . , SAn may be electrically connected to one bit line BL1 of the bit lines BL1, BL2, . . . , BLn and one complementary bit line BLB1 of the complementary bit lines BLB1, BLB2, . . . , BLBn.

The bit lines BL and the sense amplifiers SA may be electrically connected by the first routing structure CS1, and the complementary bit lines BLB and the sense amplifiers SA may be electrically connected by the second routing structure CS2.

Each of the routing structures CS may include routing through-vias 145. For example, the first routing structure CS1 may include first routing through-vias 145a in the first connection region SAC1. The second routing structure CS2 may include second routing through-vias 145b in the second connection region SAC2.

The first sense amplifier SA1 may include a plurality of transistors P1_a, P1_b, N1_a, and N1_b.

The transistors P1_a, P1_b, N1_a, and N1_b may include a P1_a transistor and a P1_b transistor, which are P-channel transistors, and an N1_a transistor and an N1_b transistor, which are N-channel transistors. The P1_a transistor and the P1_b transistor may be referred to as a P-channel transistor pair, and the N1_a transistor and the N1_b transistor may be referred to as an N-channel transistor pair.

In one or more example embodiments, the P-channel transistor may be a p-channel metal-oxide semiconductor (PMOS) transistor and the N-channel transistor may be an n-channel metal-oxide semiconductor (NMOS) transistor.

The source of the transistor P1_a and the source of the transistor P1_b may be connected to the first control line LA through a first node ND1_a. The source of the N1_a transistor and the source of the N1_b transistor may be connected to the second control line LAB through the second node ND1_b.

The first node ND1_a and the second node ND1_b may be referred to as a first source node and a second source node, respectively.

The drain of the transistor P1_a and the drain of the transistor N1_a may be connected to the first bit line BL1 through a first drain node ND1_c. The first bit line BL1 may be electrically connected to the first drain node ND1_c by the first routing structure (CS1 of FIG. 2) including the first routing through-vias 145a.

The drain of the transistor P1_b and the drain of the transistor N1_b may be connected to the first complementary bit line BLB1 through a second drain node ND1_d. The first complementary bit line BLB1 may be electrically connected to the second drain node ND1_d by the second routing structure (CS2 of FIG. 2) including the second routing through-vias 145b.

The sense amplifier SA1 may sense and amplify the voltage variation of the bit line BL1. When the sense amplifier SA1 performs sensing and amplification operations, an internal power supply voltage of the semiconductor device 1 may be applied to the first node ND1_a through the first control line LA, and the second node ND1_b may be connected to a ground terminal through the second control line LAB.

The sense amplifier SA1 of FIG. 4 includes a P-channel transistor pair and an N-channel transistor pair, and is implemented as a circuit configuration cross-coupled between transistors, but this is an example embodiment, and example embodiments are not limited thereto. For example, according to one or more example embodiments, the circuit of the sense amplifier SA1 of FIG. 4 may be implemented with various circuit configurations.

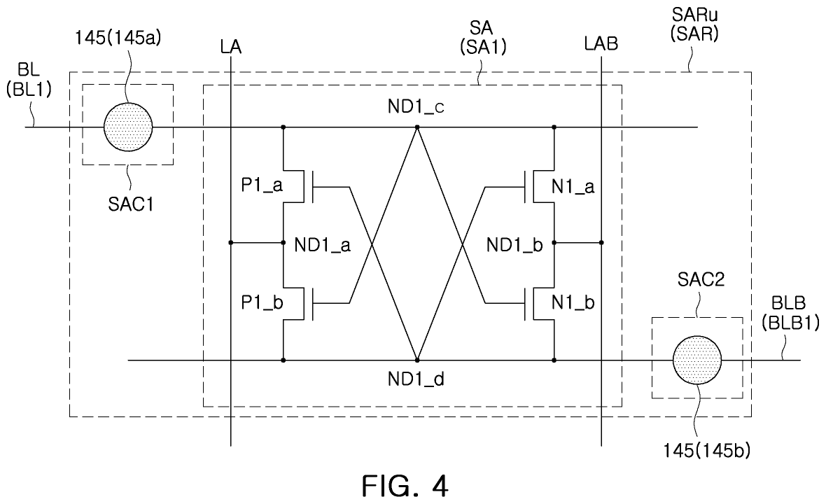

Next, elements of a semiconductor device according to one or more example embodiments will be described with reference to FIGS. 1, 2, 3 and 4 and FIGS. 5A, 5B, 5C and 5D. FIG. 5A is a plan view illustrating a memory cell array region MCA and the bit lines BL in the first memory area CR1, according to one or more example embodiments, FIG. 5B is a plan view illustrating unit sense amplifier regions SARu provided in the sense amplifier array region SAR, according to one or more example embodiments, FIG. 5C is a block diagram illustrating the unit sense amplifier region SARu, according to one or more example embodiments, and FIG. 5D is a plan view illustrating a pad array region PADR in which unit bonding pad regions PADu are provided, according to one or more example embodiments.

Referring to FIGS. 5A, 5B, 5C and 5D together with FIGS. 1, 2, 3 and 4, the memory cell array region MCA may have a quadrangular shape having a first length L1 in the second direction Y and a second length L2 in the first direction X. Each of the bit lines BL may have a line shape extending in the first direction X, and the bit lines BL may be spaced apart from each other in the second direction Y.

The bit lines BL may be provided to have a first pitch a. According to one or more example embodiments, the first pitch a may be defined as a distance between a first side of one bit line and a first side of another bit line in a pair of adjacent bit lines among the bit lines BL. In this case, the “first side” may be a side in either direction.

The sense amplifier array region SAR may have a quadrangular shape having a third length D1 in the second direction Y and a fourth length D2 in the first direction X. The memory cell array region MCA may vertically overlap the sense amplifier array region SAR.

The unit sense amplifier regions SARu may be provided two-dimensionally in the first direction X and the second direction Y Each of the unit sense amplifier regions SARu may have a quadrangular shape having a fifth length d1 in the second direction Y and a sixth length d2 in the first direction X. Each of the unit sense amplifier regions SARu may include the first and second connection regions SAC1 and SAC2, and the sense amplifier SA between the first and second connection regions SAC1 and SAC2, as described above.

The pad array region PADR in which the unit bonding pad regions PADu are provided may have a quadrangular shape having a seventh length a in the second direction Y and an eighth length R in the first direction X.

Within the pad array region PADR, the unit bonding pad regions PADu may be two-dimensionally provided in the first direction X and the second direction Y Each of the unit bonding pad regions PADu may have a quadrangular shape having a ninth length b in the second direction Y and a tenth length c in the first direction X.

A routing bonding pad may be provided in each of the unit bonding pad areas PADu. The routing bonding pads PAD provided in the pad array region PADR may be spaced apart from each other.

The lower chip structure LC may include the memory cell array regions MCA in the memory areas CR. For example, the first memory area CR may include the memory cell array region MCA.

The upper chip structure UC may include the sense amplifier array region SAR. The sense amplifier array region SAR of the upper chip structure UC may vertically overlap the memory cell array region MCA.

Each of the lower and upper chip structures LC and UC may include a pad array region PADR. The pad array region PADR of the lower chip structure LC and the pad array region PADR of the upper chip structure UC may face each other and may be bonded to each other. The pad array region PADR of each of the lower and upper chip structures LC and UC may vertically overlap the memory cell array region MCA and the sense amplifier array region SAR.

In one or more example embodiments, the number N1 of the routing pads PAD provided in the second direction Y in the pad array region PADR may be determined by Equation 1 below.

$$N 1 = \frac{D 1}{b} + n , ( n = 1 , 2 , 3 , ... ) \qquad Equation 1$$

In Equation 1, N1 is the number N1 of the routing pads PAD provided in the second direction Y within the pad array region PADR, b is the ninth length b, and D1 is the third length D1, and n may be a positive integer.

In one or more example embodiments, the number N2 of the routing pads PAD provided in the first direction X may be determined by the following Equation 2>.

$$N 2 = \frac{D 2}{c} + n , ( n = 1 , 2 , 3 , ... ) \qquad Equation 2$$

In Equation 2, N2 is the number N2 of the routing pads PAD provided in the first direction X within the pad array region PADR, c is the tenth length c, and D2 is the fourth length D2, and n may be a positive integer.

In one or more example embodiments, the routing pads PAD and the bit lines BL may be provided to satisfy the condition of Equation 3 below.

$$N 1 \times N 2 > \frac{L 1}{a} \qquad Equation 3$$

In Equation 3, a may be the first pitch a, and L1 may be the first length L1.

In one or more example embodiments, the number N3 of the bit lines BL vertically overlapping the unit bonding pad area PADu may be determined by Equation 4 below.

$$N 3 = \frac{b}{a} \pm n , ( n = 1 , 2 , 3 , ... ) \qquad Equation 4$$

In Equation 4, N3 is the number N3 of the bit lines BL vertically overlapping the unit bonding pad area PADu, a is the first pitch a, and b is the ninth length b, and n may be a positive integer.

In one or more example embodiments, the unit bonding pad area PADu and the unit sense amplifier region SARu may be determined by the following Equation 5 and Equation 6.

$$b = {n}_{1} \times d 1 , ( {n}_{1} = 1 , 2 , 3 , ... ) \qquad Equation 5$$

In Equation 5, b is the ninth length b of the unit bonding pad area PADu in the second direction Y, and d1 may be the fifth length d1 of the unit sense amplifier region (SARu) in the second direction Y

$$D 2 = {n}_{2} \times d 2 , ( {n}_{2} = 1 , 2 , 3 , ... ) \qquad Equation 6$$

In Equation 6, D2 may be the fourth length D2 of the sense amplifier array region SAR in the first direction X, and d2 may be the sixth length d2 of the unit sense amplifier region SARu in the first direction X.

In one or more example embodiments, the unit bonding pad area PADu and the unit sense amplifier region SARu may satisfy the following Expression 7.

$${n}_{1} \times {n}_{2} \geq N 2 \qquad Equation 7$$

In Expression 7, the number N2 of the routing pads PAD provided in the first direction X determined by Equation 2 may be an odd number or an even number.

In one or more example embodiments, when the number of unit sense amplifier regions SARu provided in the first direction X in the sense amplifier array region SAR is N4, the following number of interconnection lines may be required between the through-vias 145 and the bit lines BL. Accordingly, the number N5 of interconnection lines provided between the through-vias 145 and the bit lines BL may be determined by Equation 8 below.

$$N 5 = \frac{( 2 \times N 4 ) - 2}{2} \qquad Equation 8$$

According to one or more example embodiments, the interconnection lines may comprise interconnection lines provided at different levels, and bonding pads may be excluded. Each of the interconnection lines may comprise a pad extending in a horizontal direction or an interconnection line including a pad, and in this case, the pad may comprise a pad contacting a plug rather than a bonding pad.

In one or more example embodiments, the number N5 of interconnection lines provided between the through-vias 145 and the bit lines BL may be one or more additional interconnection lines that are required for alignment between the through-vias 145 and the bonding pads PAD.

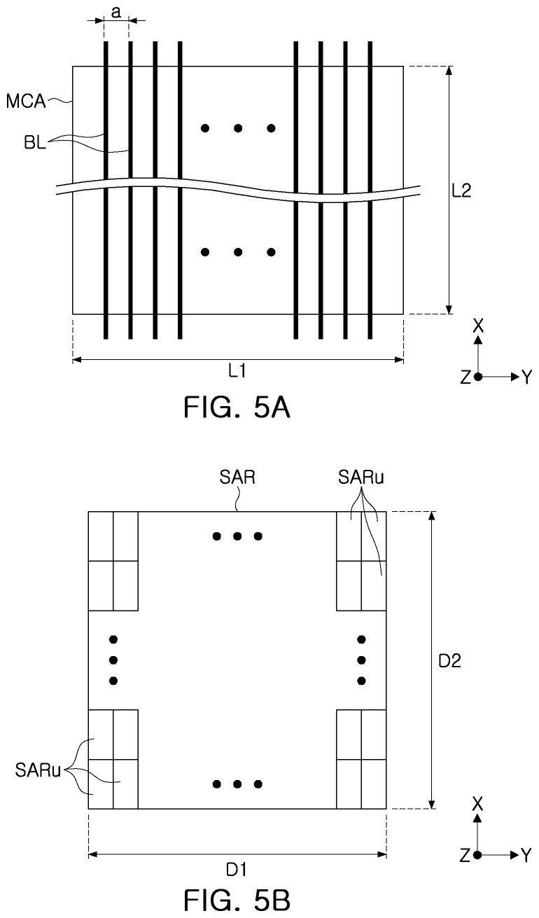

Next, elements of a semiconductor device according to one or more example embodiments will be described with reference to FIG. 6 along with FIGS. 1, 2, 3, 4, 5A, 5B, 5C and 5D described above. FIG. 6 is a diagram illustrating the above-described electrical connection relationship between the unit sense amplifier regions SARu, the bonding pads PAD of the unit pad regions PADR, and routing through-vias 145. In detail, FIG. 6 is a conceptual diagram illustrating the electrical connection relationship between first, second, third and fourth bit lines BL1, BL2, BL3, and BL4 among the bit lines BL, first, second, third and fourth complementary bit lines BLB1, BLB2, BLB3 and BLB4 among the complementary bit lines (BLB), and the first, second, third and fourth unit sense amplifiers SARu1, SARu2, SARu3, and SARu4 among the unit sense amplifier regions (SARu).

Referring to FIG. 6 along with FIGS. 1, 2, 3, 4, 5A, 5B, 5C and 5D, each of the sense amplifiers SA of the unit sense amplifier regions SARu may be electrically connected to one bit line BL and one complementary bit line BLB by routing structures CS. For example, the sense amplifier SA1 of the first unit sense amplifier region SARu1 may be electrically connected to the first bit line BL1 and the first complementary bit line BLB1, the sense amplifier SA2 of the second unit sense amplifier region SARu2 may be electrically connected to the second bit line BL2 and the second complementary bit line BLB2, the amplifier SA2 of the third unit sense amplifier region SARu3 may be electrically connected to the third bit line BL3 and the third complementary bit line BLB3, and the sense amplifier SA2 of the fourth unit sense amplifier region SARu4 may be electrically connected to the fourth bit line BL4 and the fourth complementary bit line BLB4.

The bit lines BL may be electrically connected to the sense amplifiers SA through the first routing through-vias 145a of the routing structures CS, and the complementary bit lines BLB may be electrically connected to the sense amplifiers SA through the second routing through-vias 145b of the routing structures CS.

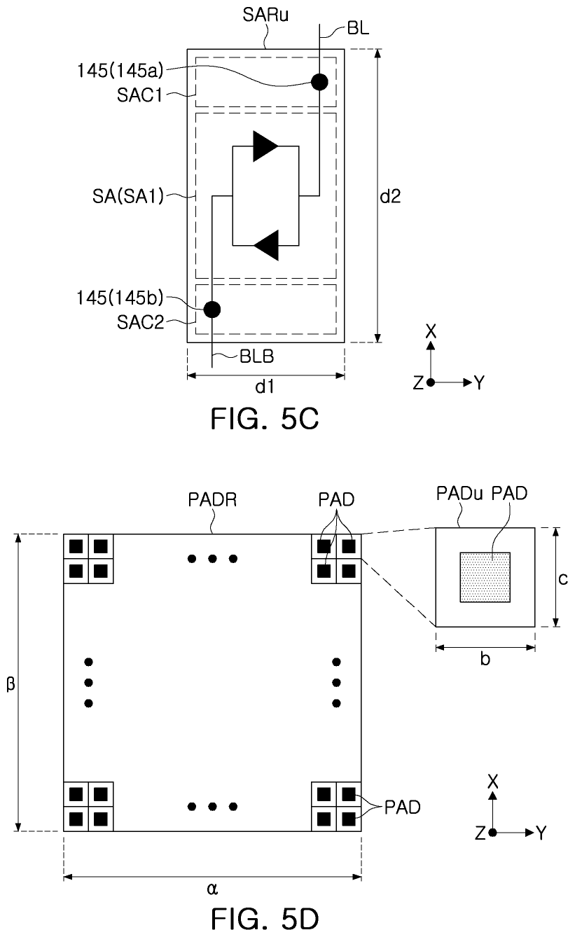

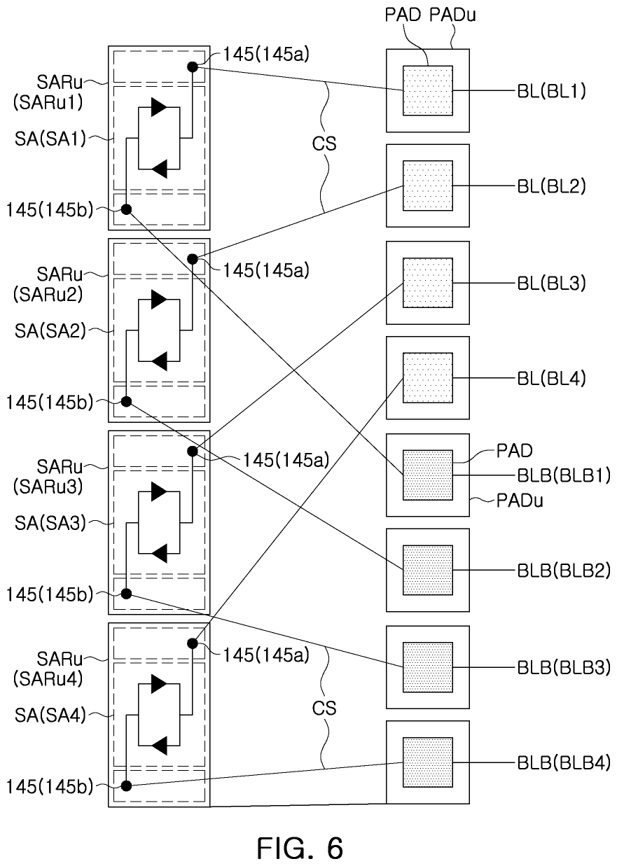

Next, the cross-sectional structure of the semiconductor device 1 described with reference to FIGS. 1A, 1B, 2, 3, 4, 5A, 5B, 5C, 5D and 6 will be described with reference to FIGS. 7A, 7B, and 8. FIG. 7A is a cross-sectional view illustrating a portion of a bank BA of a semiconductor device according to one or more example embodiments, FIG. 7B is a cross-sectional view illustrating a portion of the first peripheral circuit PER1 of the semiconductor device according to one or more example embodiments, and FIG. 8 is a partially enlarged view of the area indicated by ‘B’ in FIG. 7A.

Referring to FIGS. 7A, 7B, and 8 along with FIGS. 1A, 1B, 2, 3, 4, 5A, 5B, 5C, 5D and 6, as described above, according to one or more example embodiments, the semiconductor device 1 may include the lower chip structure LC and the upper chip structure UC sequentially stacked.

As described above, the lower chip structure LC may include the first peripheral circuit area PER1, the first memory area CR1, the second memory area CR2, and an extension area EXTb between the first and second memory areas CR1 and CR2.

The lower chip structure LC may include a lower base 5, memory structures MS and a power capacitor CAPp on the lower base 5, lower interconnection structures 25 electrically connected to the memory structures MS and the power capacitor CAPp, on the lower base 5, a lower insulating structure 20 covering the memory structures MS and the lower interconnection structures 25, on the lower base 5, and a lower bond insulating layer 60 and lower bond pads 65 on the lower insulating structure 20.

Each of the memory structures MS may include word lines ML, bit lines BLa and BLb, and data storage structures DS. Each of the data storage structures DS may include first electrodes SN, a second electrode PL covering the first electrodes SN, and a dielectric layer DI between the first electrodes SN and the second electrode PL.

The lower base 5 may include a lower semiconductor substrate and an isolation region cSTI on the lower semiconductor substrate. The word lines WL may be buried in the lower base 5.

The data storage structures DS may be memory cell capacitors capable of storing data in a memory such as a dynamic random access memory (DRAM) or the like.

The first peripheral circuit area PER1 may include the power capacitor CAPp. The power capacitor CAPp may include a lower electrode ELa, an upper electrode ELb, and a dielectric layer DIb between the lower and upper electrodes ELa and ELb. The lower electrode ELa may include a first lower electrode ELa1, second lower electrodes ELa2 on the first lower electrode ELa1, and third lower electrodes ELa3 on the second lower electrodes ELa2. The third lower electrodes ELa3 may be provided at substantially the same level as the first electrodes SN.

The first memory area CR1 may include a first memory structure from among the memory structures MS, and the second memory area CR2 may include a second memory structure from among the memory structures MS.

Among the bit lines BLa and BLb, the first memory structure MS of the first memory area CR1 may include a first bit line indicated by BLa, and the first bit line BLa may be a bit line BL electrically connected to the above-described sense amplifier SA.

Among the bit lines BLa and BLb, the second memory structure MS of the second memory area (CR2 in FIGS. 1B and 2) may include a second bit line indicated by BLb. The second bit line BLb may be the complementary bit line BLB electrically connected to the above-described sense amplifier SA.

Hereinafter, the first bit line BLa will be described by referring to a bit line BL electrically connected to the above-described sense amplifier SA, and the second bit line BLb will be described by referring to the complementary bit line BLB electrically connected to the sense amplifier SA described above.

The lower interconnection structures 25 may include a first lower routing interconnection structure 25a electrically connected to the bit line BL, a second lower routing interconnection structure 25b electrically connected to the complementary bit line BLB, and a third lower routing interconnection structure 25c electrically connected to the upper electrode ELb.

Each of the lower interconnection structures 25 may include at least two horizontal portions 30L and 32L provided at different levels and may include vertical portions 30V, 32V, and 34V provided at different levels.

In one or more example embodiments, a “vertical portion” may include a vertically extending plug or via, and a “horizontal portion” may include a horizontally extending pad or an interconnection line including a pad. Accordingly, a “vertical portion” may be referred to as a plug or via, and a “horizontal portion” may be referred to as an interconnection line.

Accordingly, each of the lower interconnection structures 25 may include the at least two interconnection lines 30L and 32L provided at different levels, and the plugs 30V, 32V and 34V electrically connected to the at least two interconnection lines 30L and 32L.

In the first and second lower routing interconnection structures 25a and 25b electrically connected to the bit line BL and the complementary bit line BLB, at least one of the at least two interconnection lines 30L and 32L may extend from the extension area EXTb to the first memory area CR1. The at least two interconnection lines 30L and 32L may include a first lower interconnection line 30L and a second lower interconnection line 32L provided at a level higher than the first lower interconnection line 30L.

In the first memory area CR1, at least one of the at least two interconnection lines 30L and 32L of the first and second lower routing interconnection structures 25a and 25b may be provided on the data storage structure DS of the memory structure MS.

The plugs 30V, 32V, and 34V of the first and second lower routing interconnection structures 25a and 25b may include a first lower plug 30V below the first lower interconnection line 30L, a second lower plug 32V between the first lower interconnection line 30L and the second lower interconnection line 32L, and a third lower plug 34V on the second lower interconnection line 32L.

The first lower routing interconnection structure 25 may include the at least two lower interconnection lines 30L and 32L provided at a higher level than the data storage structure DS and provided at different levels, at least one intermediate plug 32V electrically connecting the at least two lower interconnection lines 30L and 32L, a lower plug 30V electrically connecting the lowest lower interconnection line 30L of the at least two lower interconnection lines 30L and 32L and the bit line contact area of the bit line BL, and an upper plug 34V electrically connecting the uppermost lower interconnection line 32L of the at least two lower interconnection liens 30L and 32L and the lower bonding pad 165a. In this case, the lower plug 30V does not vertically overlap the data storage structure DS, and at least one of the at least two lower interconnection lines 30L and 32L may include an area that does not vertically overlap with the data storage structure DS and may include an area that vertically overlaps with the data storage structure DS.

The bit line BL may extend from the first memory area CR1 to the extension area EXTb. The bit line BL may have a contact area that contacts the first lower plug 30V of the first lower routing interconnection structure 25a in the extension area EXTb. The complementary bit line BLB may have a bit line contact area contacting the first lower plug 30V of the second lower routing interconnection structure 25b within the extension area EXTb.

The lower bonding pads 65 may include lower routing bonding pads 65a and 65b electrically connected to the first and second lower routing interconnection structures 25a and 25b.

The lower routing bonding pads 65a and 65b may be provided in the first memory area CR1. The lower routing bonding pads 65a and 65b may be provided on the memory structure MS. The lower routing bonding pads 65a and 65b may vertically overlap the data storage structure DS of the memory structure MS. In the first memory area CR1, at least one of the at least two interconnection lines 30L and 32L of the first and second lower routing interconnection structures 25a and 25b may vertically overlap the data storage structure DS, on the data storage structure DS of the memory structure MS.

The third lower plugs 34V of the first and second lower routing interconnection structures 25a and 25b may be electrically connected to the lower routing bonding pads 65a and 65b. The lower routing bonding pads 65a and 65b may include a first lower routing bonding pad 65a connected to the first lower routing interconnection structure 25a, and a second lower routing bonding pad 65b electrically connected to the second lower routing interconnection structure 25b. The first lower routing bonding pad 65a may contact and may be connected to the third lower contact plug 34V of the first lower routing interconnection structure 25a, and the second lower routing bonding pad 65b may contact and may be connected to the third lower contact plug 34V of the second lower routing interconnection structure 25b.

Upper surfaces of the lower bonding pads 65 and the lower bonding insulating layer 60 may be coplanar.

The upper chip structure UC may include upper bonding pads 165, an upper bonding insulating layer 160, an intermediate insulating structure 155, intermediate connection structures 150, an upper base 105, peripheral transistors (PTR), first upper interconnection structures 125, a first upper insulating structure 120, second upper interconnection structures 175, a second upper insulating structure 170, the capping insulating layer 185, an input/output pad 190, through-vias 145 and insulating spacers 147.

The upper bonding insulating layer 160 and the upper bonding pads 165 may be provided below the upper base 105.

The upper bonding insulating layer 160 may contact and may be bonded to the lower bonding insulating layer 60. The lower bonding insulating layer 60 may include the same material as the upper bonding insulating layer 160. Each of the lower and upper bonding insulating layers 60 and 160 may include at least one of silicon oxide, SiCN, and SiCON.

The upper bonding pads 165 may be bonded while contacting the lower bonding pads 65. The upper bonding pads 165 may include the same metal material as the lower bonding pads 65, for example, copper.

The upper bonding pads 165 may include upper routing bonding pads 165a and 165b electrically connected to and bonded to the lower routing bonding pads 65a and 65b. For example, the upper routing bonding pads 165a and 165b may include a first upper routing bonding pad 165a connected to the first lower routing bonding pad 65a, and a second upper routing bonding pad 165b connected to the second lower routing bonding pad 65b.

The lower and upper routing bonding pads 65a, 65b, 165a, and 165b may comprise the routing bonding pads PAD described with reference to FIGS. 5D and 6. Accordingly, the lower chip structure LC may include the routing bonding pad array region (PADR in FIG. 5D) in which the lower routing bonding pads 65a and 65b are provided, and the upper chip structure LC may include the routing bonding pad array region (PADR in FIG. 5D) in which the upper routing bonding pads 165a and 165b are provided.

The routing bonding pad array region (PDAR in FIG. 5D) may vertically overlap the data storage structure DS of the memory structure MS of the first memory area CR1.

The first lower routing bonding pad 65a and the first upper routing bonding pad 165a bonded to each other may comprise routing bonding pads PAD electrically connected to the bit line BL. The second lower routing bonding pad 65b and the second upper routing bonding pad 165b bonded to each other may be routing bonding pads PAD electrically connected to the complementary bit line BLB.

The intermediate connection structures 150 and the intermediate insulating structure 155 may be provided on the upper bonding insulating layer 160 and the upper bonding pads 165 and may be provided below the upper base 105. The intermediate connection structures 150 may be provided within the intermediate insulating structure 155.

Each of the intermediate connection structures 150 may include at least one intermediate interconnection line 152L and intermediate plugs 152V1 and 152V2 connected to the at least one intermediate interconnection line 152L. For example, the intermediate plugs 152V1 and 152V2 may include a first intermediate plug 152V1 on the at least one intermediate interconnection line 152L and a second intermediate plug 152V2 below the at least one intermediate interconnection line 152L.

The intermediate connection structures 150 may include intermediate routing connection structures 150a and 150b electrically connected to the upper routing bonding pads 165a and 165b. The intermediate routing connection structures 150a and 150b may include a first intermediate routing connection structure 150a connected to the first upper routing bonding pad 165a, and a second intermediate routing connection structure 150b connected to the second upper routing bonding pad 165b.

The upper base 105 may be provided on the intermediate insulating structure 155 and the intermediate connection structure 150. The upper base 105 may include an upper semiconductor substrate 110, a lower protective insulating layer 140 below the upper semiconductor substrate 110, upper active regions pACT on the upper semiconductor substrate 110, and an upper isolation region pSTI on the upper semiconductor substrate 110, which may define the upper active regions pACT.

The peripheral transistors PTR may include upper gates PGox and PGE on the upper active region pACT and upper source/drains PSD in the upper active region pACT on both sides of the upper gates PGox and PGE, respectively. The upper gate (PGox, PGE) may include an upper gate electrode PGE and an upper gate dielectric layer PGox between the upper gate electrode PGE and the upper active region pACT.

The peripheral transistors PTR may include transistors vertically overlapping the memory structures MS of the first and second memory areas CR1 and CR2, and transistors vertically overlapping the first peripheral circuit area PER1. For example, the peripheral transistors PTR may include first and second transistors (PTR1 and PTR2 in FIG. 8) that may configure the plurality of transistors (P1_a, P1_b, N1_a, and N1_b of FIG. 4) of the sense amplifiers SA, while vertically overlapping the memory structure MS of the first memory area CR1.

The first upper interconnection structures 125 may form a peripheral circuit by electrically connecting the peripheral transistors PTR, on the upper base 105. Each of the first upper interconnection structures 125 may include vertical portions 130V and 132V provided at different levels and horizontal portions 130L and 132L provided at different levels.

The first upper interconnection structures 125 may include first and second upper routing interconnection structures 125a and 125b electrically connected to the first and second transistors (PTR1 and PTR2 in FIG. 8) that may constitute the plurality of transistors (P1_a, P1_b, N1_a, and N1_b in FIG. 4) of the sense amplifiers SA.

The first upper insulating structure 120 may be provided on the upper base 105 and may cover the peripheral transistors PTR and the first upper interconnection structures 125.

The through-vias 145 may pass through the upper base 105. The through-vias 145 may electrically connect the first upper interconnection structures 125 to the intermediate connection structures 150. The through-vias 145 may be connected to a first horizontal portion 130L positioned in a lower portion from among the horizontal portions 130L and 132L of the first upper interconnection structures 125.

The through-vias 145 may include routing through-vias 145a and 145b. The routing through-vias 145a and 145b may include a first routing through-via 145a electrically connecting the first upper routing interconnection structure 125a and the first intermediate routing connection structure 150a, and a second routing through-via 145b electrically connecting the second upper routing interconnection structure 125b and the second intermediate routing connection structure 150b.

The first routing through-via 145a may pass through the upper base 105 below the first connection region SAC1, and the second routing-through-via 145b may pass through the upper base 105 below the second connection region SAC2.

Each of the through-vias 145 may include a conductive pillar 142a and a barrier layer 142b covering side and lower surfaces of the conductive pillar 142a.

The through-vias 145 may have inclined side surfaces of which a width decreases in a direction from bottom to top.

The insulating spacers 147 may cover side surfaces of the through-vias 145.

In one or more example embodiments, the bit line BL in the first memory area CR1 may be electrically connected to the peripheral transistors PTR constituting the sense amplifier SA by the first lower routing interconnection structure 25a, the first lower routing bonding pad 65a, and the first routing through-via 145a, and the first upper routing interconnection structure 125a.

In one or more example embodiments, the complementary bit line BLB in the second memory area (CR2 in FIGS. 2 and 3) may be electrically connected to the peripheral transistors PTR constituting the sense amplifier SA by the second lower routing interconnection structure 25b, the second lower routing bonding pad 65b, the second routing-through-via 145b, and the second upper routing interconnection structure 125b.

The second upper interconnection structures 175 may include vertical portions 172V, 174V, 176V, and 178V provided at different levels, and horizontal portions 172L, 174L, and 176L provided at different levels. At least one of the horizontal portions 172L, 174L, and 176L of the second upper interconnection structures 175 may have a greater thickness than a thickness of the horizontal portions 130L and 132L of the first upper interconnection structures 125. The second upper insulating structure 170 may cover the second upper interconnection structures 175, on the first upper insulating structure 120. The capping insulating layer 185 may be provided on the second upper insulating structure 170.

The input/output pad 190 may be electrically connected to the second upper interconnection structures 175, and a side surface thereof may be surrounded by the second upper insulating structure 170. An upper surface of the input/output pad 190 may be exposed.

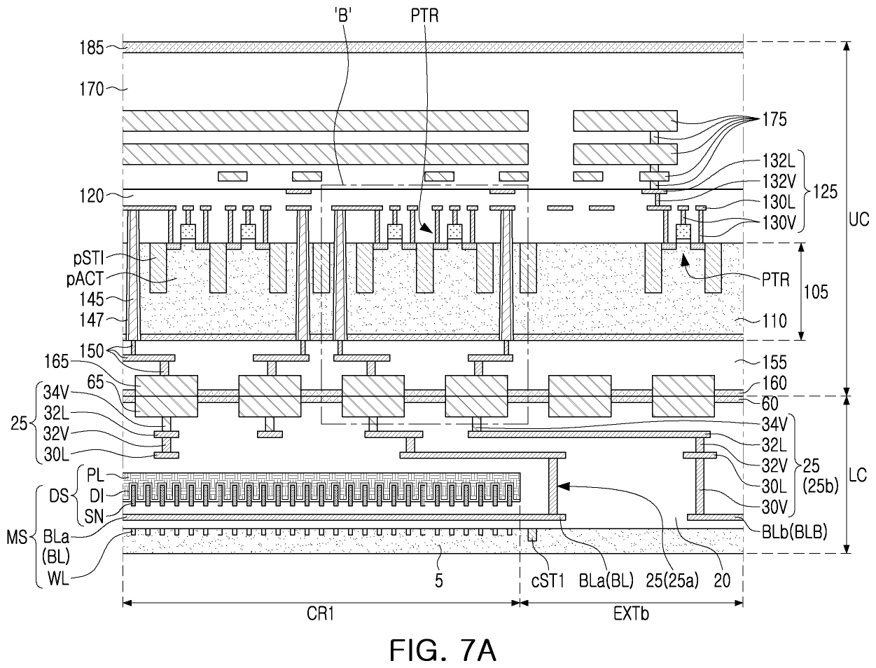

Next, referring to FIG. 9, an illustrative example of planar arrangement of the intermediate routing connection structures 150a and 150b, the upper routing bonding pads 165a and 165b, and the routing through-vias 145a and 145b in FIGS. 7A, 7B and 8 will be described according to one or more example embodiments. FIG. 9 is a plan view illustrating the intermediate routing connection structures 150a and 150b, the upper routing bonding pads 165a and 165b, and the routing through-vias 145a and 145b.

Referring to FIG. 9 together with FIGS. 7A, 7B, and 8 described above, the upper routing bonding pads 165a and 165b may be respectively provided in unit bonding pad regions 165R. The unit bonding pad regions 165R may correspond to the unit bonding pad region PADu described with reference to FIG. 5D.

The routing through-vias 145a and 145b may vertically overlap the unit bonding pad regions 165R.

At least a portion of the first routing through-via 145a may not vertically overlap the first upper routing bonding pad 165a. At least a portion of the second routing through-via 145b may not vertically overlap the second upper routing bonding pad 165b.

In the first intermediate routing connection structure 150a, the first intermediate vertical portion 152V1 may be connected to the first routing through-via 145a while vertically overlapping the first routing through-via 145a, the second intermediate vertical portion 154V2 may be connected to the first upper routing bonding pad 165a while vertically overlapping the first upper routing bonding pad 165a, and the intermediate interconnection line 152L may be connected to the first and second intermediate vertical portions 154V1 and 154V2. In the first intermediate routing connection structure 150a, a plurality of second intermediate vertical portions 154V2 may be provided, and the plurality of second intermediate vertical portions 154V2 may be connected to the intermediate interconnection line 152L and the to the first upper routing bonding pad 165a.

In the second intermediate routing connection structure 150b, the first intermediate vertical portion 152V1 may be connected to the second routing through-via 145b while vertically overlapping the second routing through-via 145b, the second intermediate vertical portion 154V2 may be connected to the second upper routing bonding pad 165b while vertically overlapping the second upper routing bonding pad 165b, and the intermediate interconnection line 152L may be connected to the first and second intermediate vertical portions 154V1 and 154V2. In the second intermediate routing connection structure 150b, a plurality of second intermediate vertical portions 154V2 may be provided, and the plurality of second intermediate vertical portions 154V2 may be connected to the intermediate interconnection line 152L and the second upper routing bonding pad 165b.

Next, various modified examples of the elements of the above-described one or more example embodiments will be described. Various modified examples of the elements of the above-described one or more example embodiments described below will be described focusing on the modified or replaced elements. According to one or more example embodiments, the elements described above may be directly cited without separate detailed description, or the description may be omitted. In addition, elements that may be modified or replaced described below are described with reference to the following drawings, but the elements that may be modified or replaced may be combined with each other or with the elements described above to configure a semiconductor device according to one or more example embodiments.

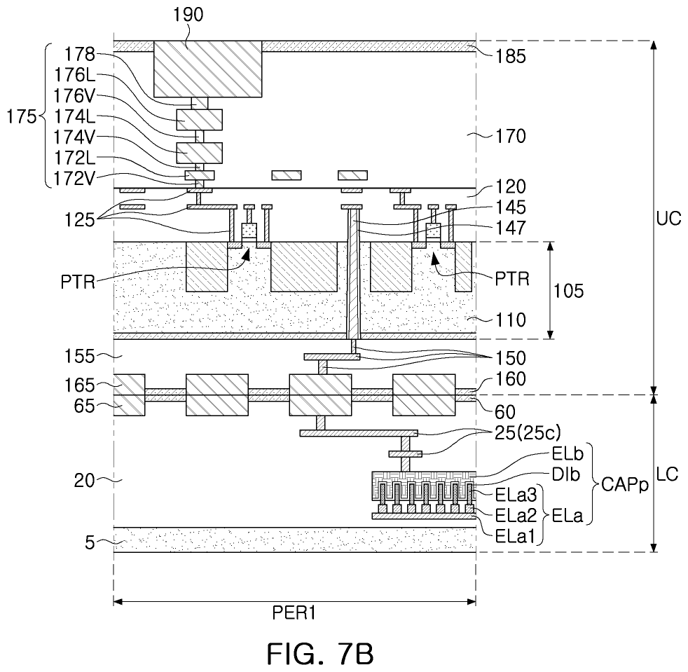

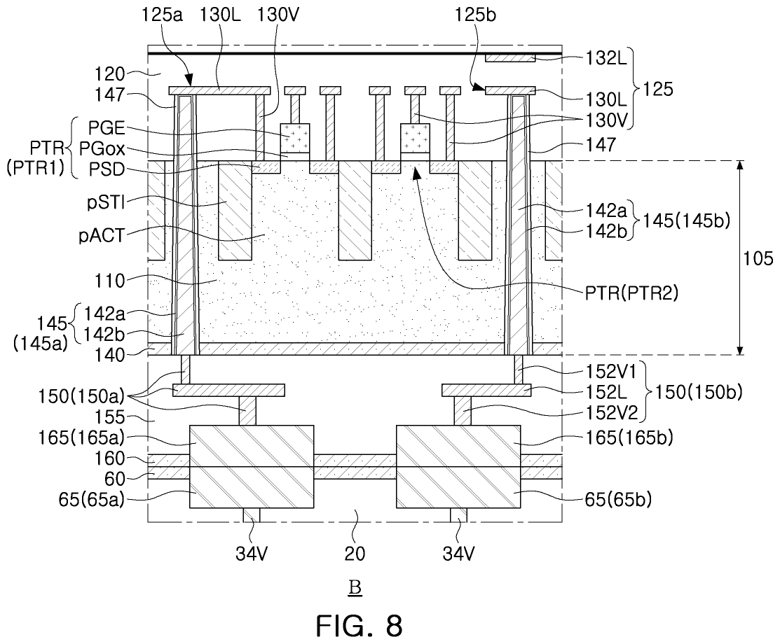

Referring to FIG. 10, a modified example of the intermediate connection structures 150, the upper bonding pads 165, and the lower bonding pads 65 will be described according to one or more example embodiments. FIG. 10 is a cross-sectional view illustrating a modified example of the intermediate connection structures 150, the upper bonding pads 165, and the lower bonding pads 65 in the cross-sectional structure of FIG. 8 according to one or more example embodiments, and FIG. 11 is a plan view illustrating a modified example of the intermediate connection structures 150 and the upper bonding pads 165 in the plan view of FIG. 9, according to one or more example embodiments.

Referring to FIGS. 10 and 11, according to one or more example embodiments each of the above-described intermediate connection structures (150 in FIGS. 7A, 7B, and 8) may be replaced with an intermediate connection structure 150_1 that may be configured as a vertical portion without a horizontal portion. Accordingly, the intermediate connection structures 150_1 may be referred to as “intermediate plugs” and described.

The upper bonding pads (165 in FIGS. 7A, 7B and 8) may be replaced with upper bonding pads 1651 connected to the intermediate connection structures 150_1 that may be configured as vertical portions without horizontal portions. The lower bonding pads (65 in FIGS. 7A, 7B and 8) may be replaced with lower bonding pads 65_1 bonded to the upper bonding pads 165_1.

The intermediate connection structures 150_1 may vertically overlap the upper bonding pads 165_1. At least a portion of each of the through-vias 145 may vertically overlap the upper bonding pads 165_1. The intermediate connection structures 150_1 may be provided between the through-vias 145 and the upper bonding pads 1651, while electrically connecting the through-vias 145 and the upper bonding pads 165_1.

In one direction in which the upper bonding pads 165_1 are sequentially provided, the through-vias 145 may be alternately provided. For example, when viewed from a plan view as illustrated in FIG. 11, an upper through-via 145 may be provided adjacent to the right corner of the upper portion of the upper bonding pad 165_1 having a quadrangular shape, and a lower through-via 145 may be provided adjacent to a lower left corner of the upper bonding pad 165_1 having a quadrangular shape.

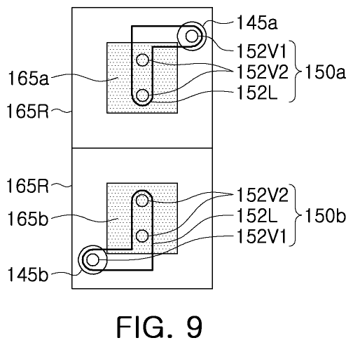

In one or more example embodiments, with reference to FIG. 12, a modified example of the intermediate connection structures 150_1 and the through-vias 145 in FIG. 11 will be described. FIG. 12 is a plan view illustrating a modified example of the intermediate connection structures 150_1 and the through-vias 145 in the plan view of FIG. 11 according to one or more example embodiments.

Referring to FIG. 12, the through-vias (145 in FIG. 11) may be replaced with through-vias 1452 sequentially provided in one direction in which the upper bonding pads 165_1 are sequentially provided, and the intermediate connection structures (150_1 in FIG. 11) may be replaced with intermediate connection structures 150_2 sequentially provided in one direction in which the upper bonding pads 165_1 are sequentially provided. For example, when viewed from a plan view as illustrated in FIG. 12, the upper through-via 1452 may be provided adjacent to a center of an upper edge of the upper bonding pad 165_1 having a quadrangular shape, and the lower through-via 1452 may be provided adjacent to a center of a lower edge of the upper bonding pad 165_1 having a quadrangular shape.

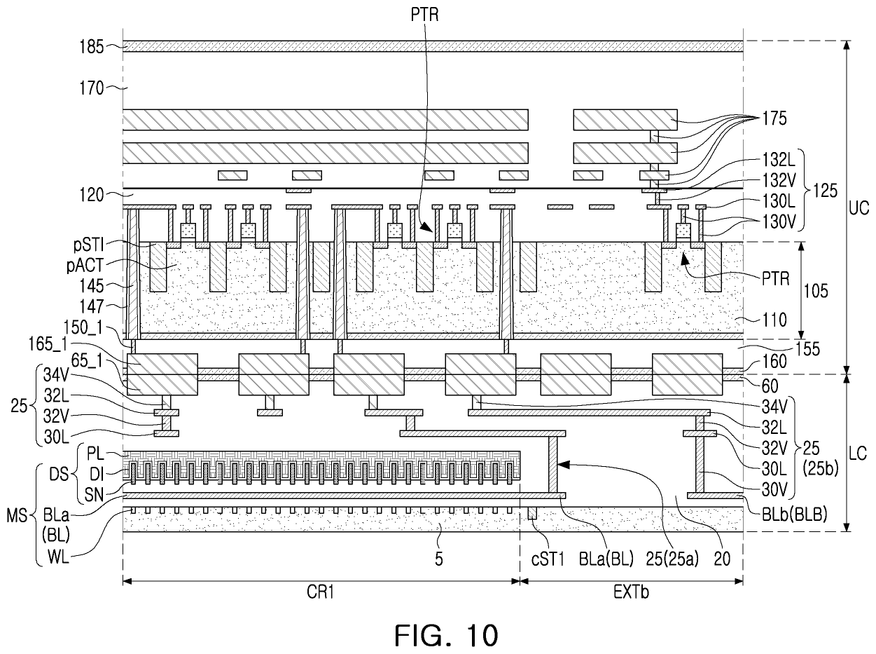

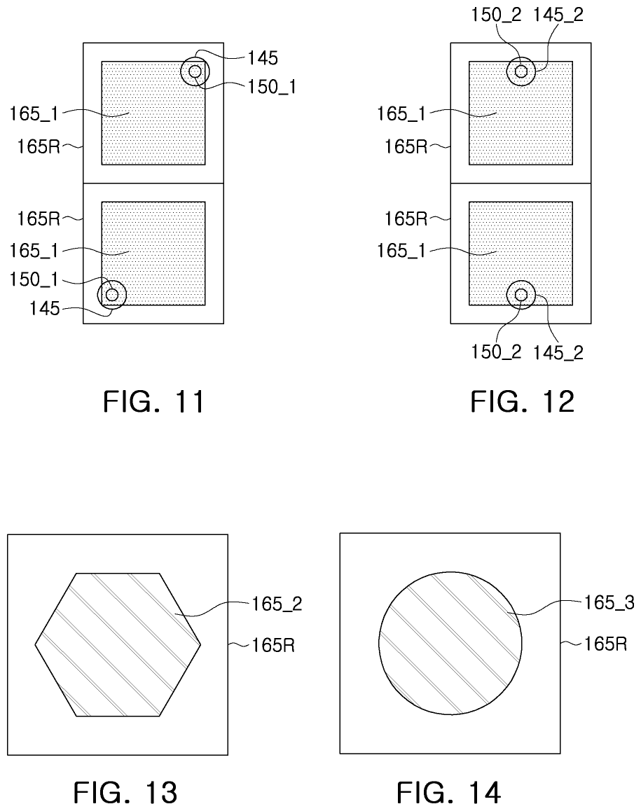

Next, with reference to FIGS. 13 and 14, various planar shapes of the upper bonding pads 165 provided in the previously described unit bonding pad regions 165R will be described according to one or more example embodiments. FIGS. 13 and 14 are plan views illustrating various planar shapes of the upper bonding pads 165 provided in the previously described unit bonding pad regions 165R according to one or more example embodiments.

In one or more example embodiments, referring to FIG. 13, the upper bonding pads 165 having a quadrangular shape described above may be modified into upper bonding pads 165_2 having a polygonal shape other than a quadrangular shape. For example, according to one or more example embodiments, each of the upper bonding pads 165_2 may have a pentagonal shape as illustrated in FIG. 13, but one or more example embodiments are not limited thereto, and the upper bonding pads 1652 may have a polygonal shape other than the pentagonal shape.

In one or more example embodiments, referring to FIG. 14, the above-mentioned upper bonding pads 165 having a quadrangular shape may be modified into upper bonding pads 165_3 having a circular shape. For example, each of the upper bonding pads 165_3 may have a circular shape as illustrated in FIG. 14, but one or more example embodiments are not limited thereto, and the upper bonding pads 165_3 may have an elliptical shape.

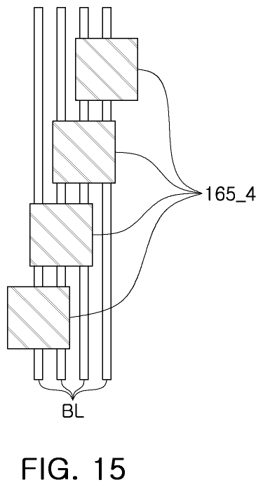

The upper bonding pads 165 described above may be sequentially provided in the length direction of the bit lines BL, but one or more example embodiments are not limited thereto. Hereinafter, a modified example of the arrangement of the upper bonding pads 165 will be described with reference to FIG. 15. FIG. 15 is a plan view illustrating a modified example of the arrangement of the bit lines BL and the upper bonding pads 165 overlapping the bit lines BL according to one or more example embodiments.

Referring to FIG. 15, in the upper bonding pads 165 overlapping the bit lines BL, the upper bonding pads 165 may be modified into upper bonding pads 165_4 sequentially provided in a diagonal direction with respect to the longitudinal direction of the bit lines BL. Each of the upper bonding pads 165_4 may have a quadrangular shape, but one or more example embodiments are not limited thereto. According to one or more example embodiments, each of the upper bonding pads 165_4 may also be modified into a polygonal shape, a circular shape, an oval shape, a diamond shape, or the like, or any shape other than a quadrangular shape.

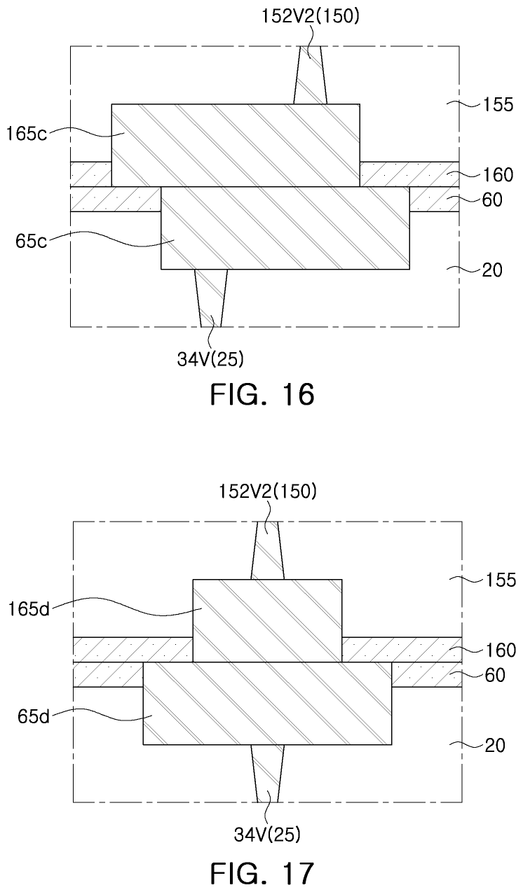

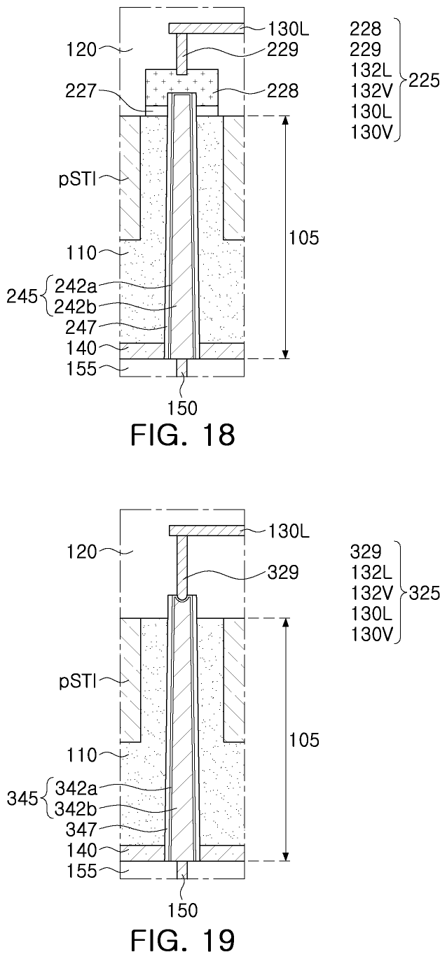

In the above-described one or more example embodiments, the lower bonding pads 65 may have the same planar shape as the upper bonding pads 165 and may be vertically aligned with the upper bonding pads 165, but one or more example embodiments are not limited thereto. Hereinafter, modifications of the lower bonding pads 65 and the upper bonding pads 165 will be described with reference to FIGS. 16 and 17, according to one or more example embodiments. According to one or more example embodiments, among the lower bonding pads 65 and the upper bonding pads 165, one lower bonding pad 65 and one upper bonding pad 165 will be mainly described.

Referring to FIG. 16, the lower bonding pad 65 and the upper bonding pad 165 that are vertically aligned as described above may be modified into lower bonding pads 65c and upper bonding pads 165c that are not vertically aligned. For example, the vertical central axis of the lower bonding pad 65c may not be aligned with the vertical central axis of the upper bonding pad 165c.

Referring to FIG. 17, according to one or more example embodiments, the lower bonding pad 65 and the upper bonding pad 165 having the same width as described above may be modified into a lower bonding pad 65d and an upper bonding pad 165d having different widths. For example, the width of the lower bonding pad 65d may be greater than the width of the upper bonding pad 165d. Alternatively, the width of the lower bonding pad 65d may be less than the width of the upper bonding pad 165d.

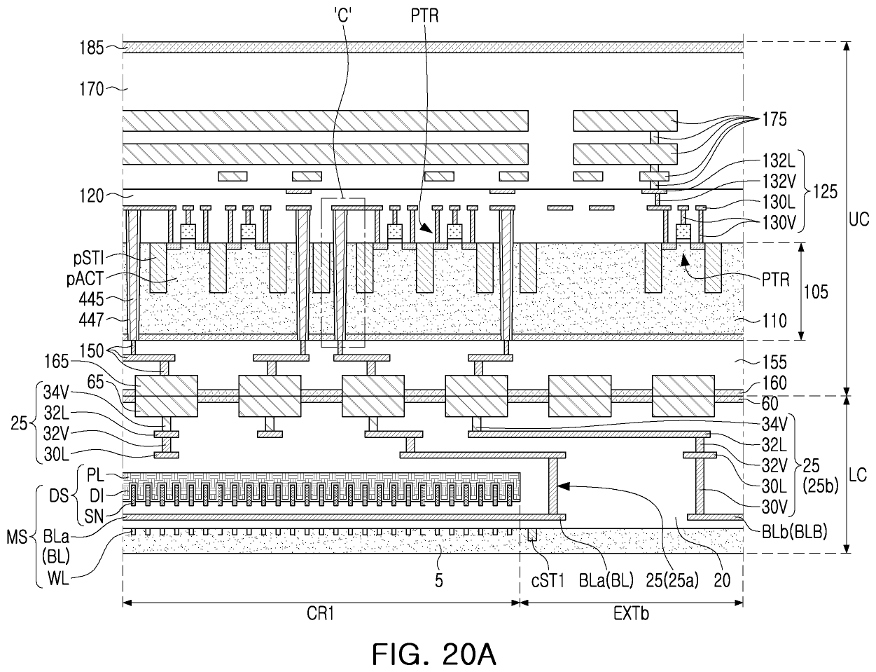

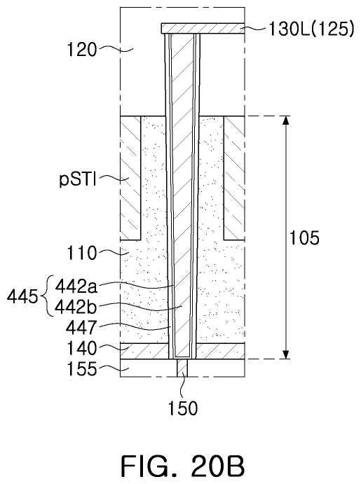

Next, various modified examples of the through-vias 145 and the first upper interconnection structures 125 according to one or more example embodiments will be described with reference to FIGS. 18 and 19, respectively. FIGS. 18 and 19 are partially enlarged cross-sectional views centered on one of the through-vias 145 to illustrate various modifications of the through-vias 145 and the first upper interconnection structures 125. Hereinafter, one of the through-vias 145 will be mainly described.

In a modified one or more example embodiments, referring to FIG. 18, the first upper interconnection structure 125 including the above-described horizontal portions 130L and 132L may be modified into a first upper interconnection structure 225 that further includes an additional horizontal portion 228 provided between the lower first horizontal portion 130L, from among the horizontal portions 130L and 132L, and the upper base 105 and an additional vertical portion 229 connecting the additional horizontal portion 228 and the first horizontal portion 130L.

The additional horizontal portion 228 is provided at the same level as the peripheral gate electrode (PGE of FIG. 8) and may be formed of the same material as the peripheral gate electrode (PGE of FIG. 8). A buffer insulating layer 227 may be provided between the additional horizontal portion 228 and the upper base 105.

The through-via (145 in FIG. 8) may be modified into a through-via 245 that penetrates the upper base 105 and extends upward to contact and be connected to the additional horizontal portion 228. The through-via 245 may include a conductive pillar 242b and a barrier layer 242a covering side and upper surfaces of the conductive pillar 242b.

The previously described insulating spacer (147 in FIG. 8) may be modified into an insulating spacer 247 covering a side surface of the through-via 245.

In a modified one or more example embodiments, referring to FIG. 19, the first upper interconnection structure 125 including the above-described horizontal portions 130L and 132L may be modified into a first upper interconnection structure 325 further including an additional vertical portion 329 provided between the first horizontal portion 130L provided in a lower portion among the horizontal portions 130L and 132L and the upper base 105.

The through-via (145 in FIG. 8) may be modified into a through-via 345 that penetrates the upper base 105 and extends upward to contact and be connected to the additional vertical portion 329. The through-via 345 may include a conductive pillar 342b and a barrier layer 342a covering side surfaces and upper surfaces of the conductive pillar 342b.

The previously described insulating spacer (147 in FIG. 8) may be modified into an insulating spacer 347 covering a side surface of the through-via 345.

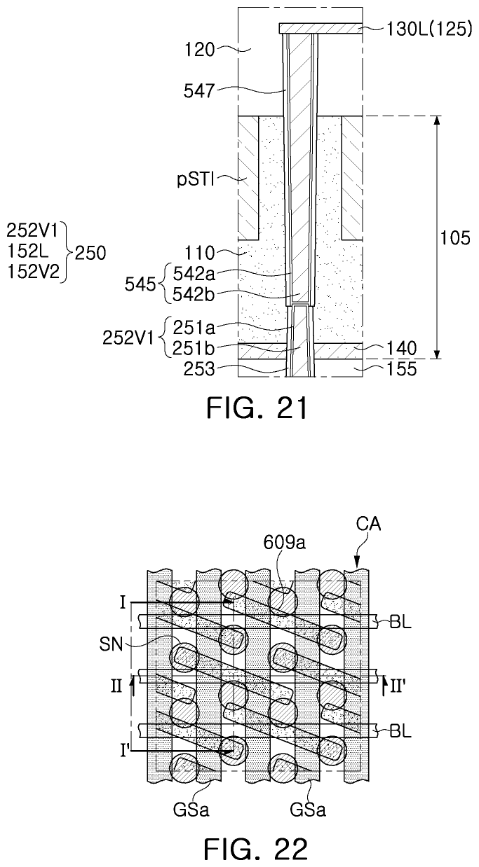

Next, a modified one or more example embodiments of the through-vias 145 will be described with reference to FIGS. 20A and 20B. FIGS. 20A and 20B are views illustrating various modifications of the through-vias 145. FIG. 20A is a cross-sectional view illustrating a modification of the through-vias 145 in the cross-sectional structure of FIG. 7A, and FIG. 20B is a partially enlarged view of the area indicated by ‘C’ in FIG. 20A.

In a modified one or more example embodiments, referring to FIGS. 20A and 20B, the above-described through-via (145 in FIG. 8) may be modified into a through-via 445 having an inclined side surface of which the upper width is greater than the lower width. The through-via 445 may include a conductive pillar 442b and a barrier layer 442a covering side and lower surfaces of the conductive pillar 442b.

The insulating spacer (147 in FIG. 8) described above may be modified into an insulating spacer 447 covering a side surface of the through-via 445.

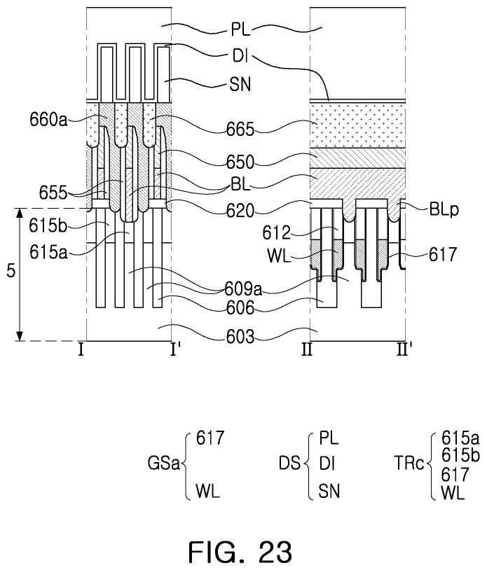

Next, FIG. 21 is a partially enlarged cross-sectional view corresponding to FIG. 20B. Referring to FIG. 21, one or more example embodiments of deformation of the through-via 445 and the intermediate connection structure 150 connected to the through-via 445 in FIG. 20B will be illustrated.

In a modified one or more example embodiments, referring to FIG. 21, the through-via 445 in FIG. 20B may be modified into a through-via 545 that extends downward while penetrating through the upper surface of the upper base 105 and is located at a level higher than the lower surface of the upper base 105.

The through-via 545 may include a conductive pillar 542b and a barrier layer 542a covering side and lower surfaces of the conductive pillar 542b.

The insulating spacer (447 in FIG. 20B) described above may be modified into an insulating spacer 547 covering a side surface of the through-via 545.

The vertical portion of the intermediate connection structure 150 connected to the through-via 545 may be modified into a vertical portion 252V1 of the intermediate connection structure that penetrates the upper base 105 and extends upward to be connected to the lower surface of the through-via 545.

The vertical portion 252V1 of the intermediate connection structure may include a conductive pillar 251b and a barrier layer 251a covering side and upper surfaces of the conductive pillar 251b.

An insulating spacer 253 covering a side surface of the vertical portion 252V1 of the intermediate connection structure may be provided. The insulating spacer 253 may separate the vertical portion 252V1 of the intermediate connection structure from the upper semiconductor substrate 110.

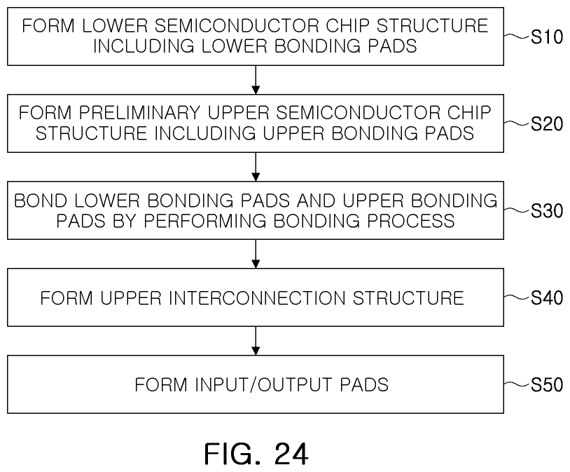

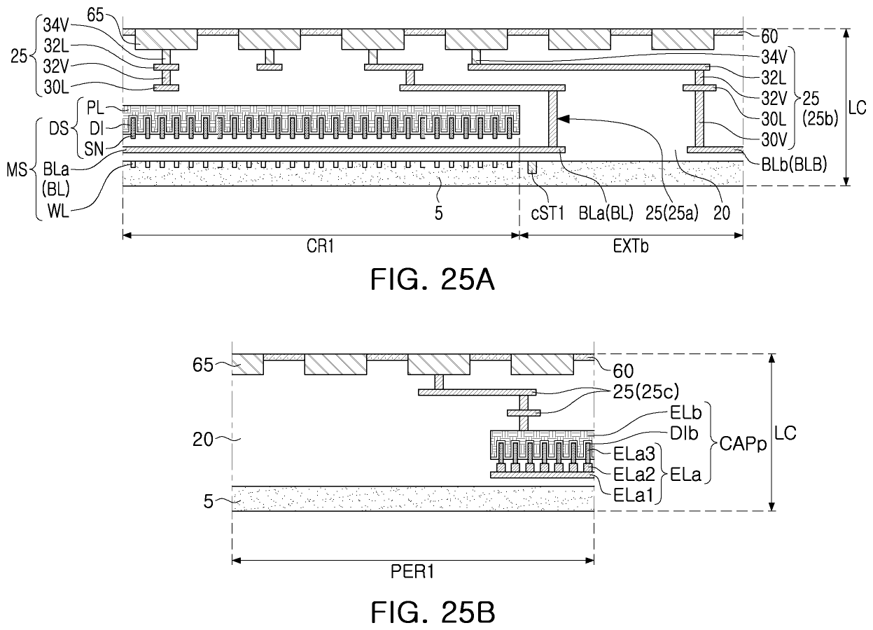

Next, with reference to FIGS. 22 and 23, one or more example embodiments of the lower chip structure LC including the above-described memory structure (MS of FIG. 7A) will be described. FIG. 22 is a plan view illustrating one or more example embodiments of the above-described memory structure (MS of FIG. 7A), and FIG. 23 is a cross-sectional view schematically illustrating areas taken along lines I-I′ and II-II′ of FIG. 22.

Referring to FIGS. 22 and 23, the lower base 5 of the lower structure LC may include a substrate 603, cell active regions 609a on the substrate 603, and a cell isolation region 606 provided on the substrate 603 and provided on side surfaces of the cell active regions 609a. The cell active regions 609a may have a shape protruding from the substrate 603 in a vertical direction. The cell isolation region 606 may be formed by shallow trench isolation. The cell isolation region 606 may be formed of an insulating material such as silicon oxide and/or silicon nitride. The cell isolation region cSTI in FIG. 7A may be formed at the same time as the cell isolation region 606.

The lower structure LC may include cell gate structures GSa buried in the cell active regions 609a and extending into the cell isolation region 606, and cell gate capping layers 612 on the cell gate structures GSa. The cell gate capping layers 617 may be formed of an insulating material.

The cell gate structures GSa and the cell gate capping layers 612 may be provided in cell gate trenches extending into the cell isolation region 606 while crossing the cell active region 609a.

Each of the gate structures GSa may include a cell gate dielectric layer 617 and a cell gate electrode WL on the cell gate dielectric layer 617. The cell gate electrodes WL may be word lines.

The lower structure LC may further include first source/drain regions 615a and second source/drain regions 615b provided in the cell active regions 609a. The cell gate structures GS and the first and second sources/drains 615a and 615b may constitute cell transistors TRc. The cell transistors TRc may comprise cell switching elements.

The lower structure LC may include a buffer insulating layer 620 on the cell active regions 609a and the cell isolation region 606, bit lines BL provided on the buffer insulating layer 620 and including plug portions BLP penetrating the buffer insulating layer 620, bit line capping layers 650 on the bit lines BL, cell contact structures 660a provided on both sides of the bit lines BL and including pad portions extending onto the bit line capping layers 650, an insulating isolation structure 665 provided between the pad portions of the cell contact structures 660a and extending downward, and insulating spacers 655 on sides of the bit lines BL and the bit capping layers 650.

The plug portions BLP of the bit lines BL may be electrically connected to the first source/drain regions 615a. The cell contact structures 660a may be electrically connected to the second source/drain regions 615b.

The data storage structure DS described with reference to FIG. 7A may be provided on the cell contact structures 660a and the insulating isolation structure 665. In the data storage structure DS, the first electrodes SN may be electrically connected to the cell contact structures 660a, the dielectric layer DI may cover the first electrodes SN, and the second electrode PL may be provided on the dielectric layer DI.

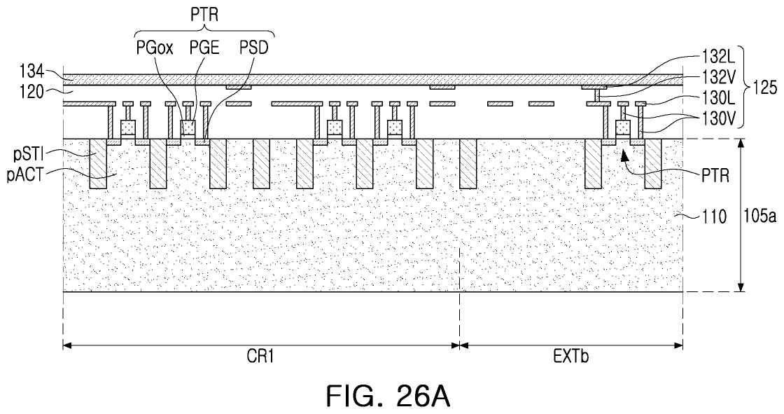

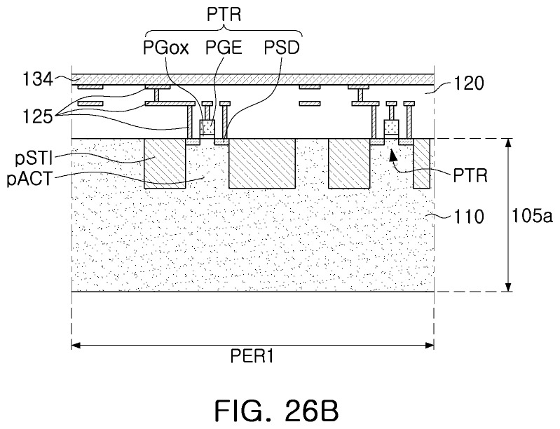

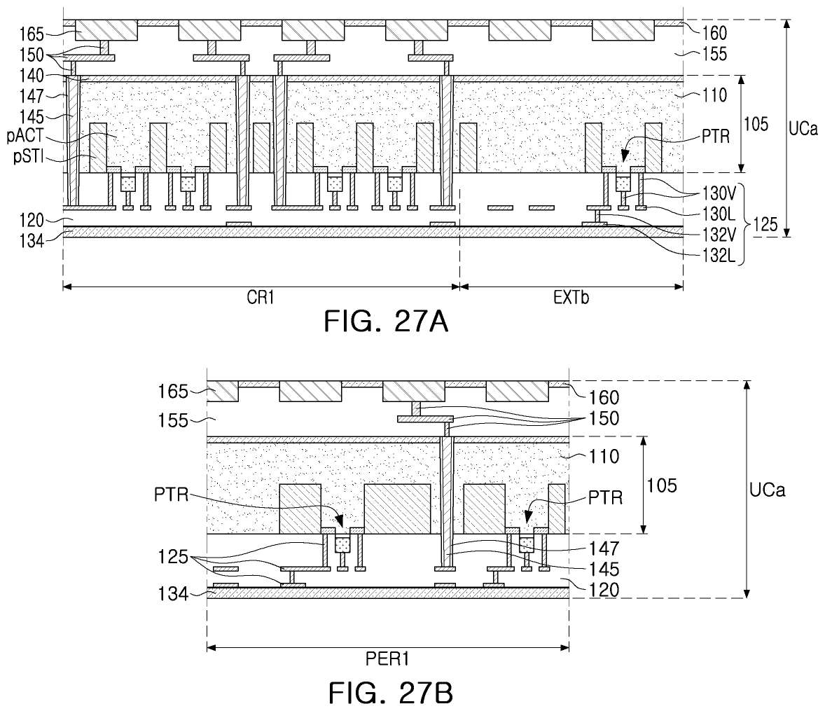

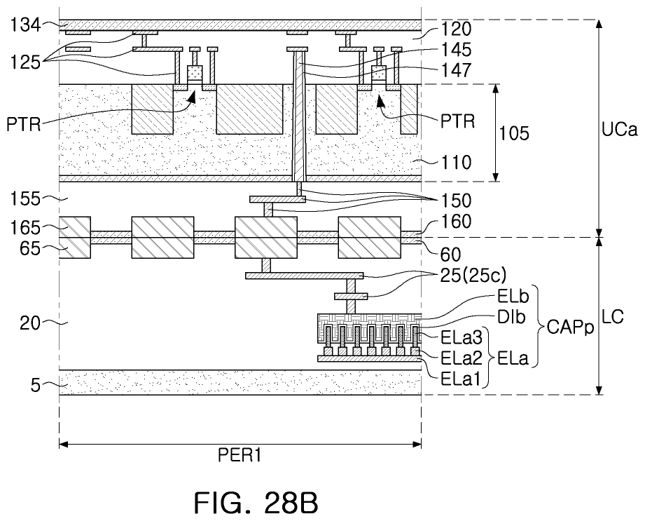

Next, with reference to FIGS. 24, 25A, 25B, 26A, 26B, 27A, 27B, 28A and 28B, an illustrative example of a method of forming a semiconductor device according to one or more example embodiments will be described. In FIGS. 24, 25A, 25B, 26A, 26B, 27A, 27B, 28A and 28B, FIG. 24 is a process flow diagram illustrating an illustrative example of a method of forming a semiconductor device according to one or more example embodiments, FIGS. 25A and 25B are cross-sectional views illustrating one or more example embodiments of a method of forming a lower chip structure, FIGS. 26A and 26B are cross-sectional views illustrating one or more example embodiments of a method of forming a first preliminary upper chip structure, FIGS. 26A and 26B are cross-sectional views illustrating one or more example embodiments of a method of forming a second preliminary upper chip structure, and FIGS. 28A and 28B are cross-sectional views illustrating bonding of a lower chip structure and a second preliminary upper chip structure. FIGS. 25A, 26A, 27A, and 28A are cross-sectional views corresponding to the cross-sectional structure of FIG. 7A, and FIGS. 25B, 26B, 27B, and 28B are cross-sectional views corresponding to the cross-sectional structure of FIG. 7B.

Referring to FIGS. 24, 25A, and 25B, according to one or more example embodiments, a lower semiconductor chip structure LC including lower bonding insulating pads 65 may be formed (S10). The lower semiconductor chip structure LC may be the lower semiconductor chip structure (LC) as described with reference to FIGS. 7A and 7B. Accordingly, the lower semiconductor chip structure LC may include the base 5, the memory structures MS, the power capacitor CAPp, the lower insulating structure 20, the lower interconnection structures 25, the lower bonding insulating layer 60, and the lower bonding pads 65 as described in FIGS. 7A and 7B. The lower bonding insulating layer 60 and the lower bonding pads 65 may have coplanar upper surfaces.

Referring to FIGS. 26A and 26B, a first preliminary upper semiconductor chip structure may be formed. Forming the first preliminary upper semiconductor chip structure may include forming a preliminary upper base 105a, forming peripheral transistors PTR on the preliminary upper base 105a, forming first upper interconnection structures 125 and a first upper insulating structure 120 covering the first upper interconnection structures 125 on the preliminary upper base 105a, and forming the protective insulating layer 134 on the first upper insulating structure 120.

Forming the preliminary upper base 105a may include forming a peripheral isolation region pSTI defining the peripheral active regions pACT on the upper semiconductor substrate 110.

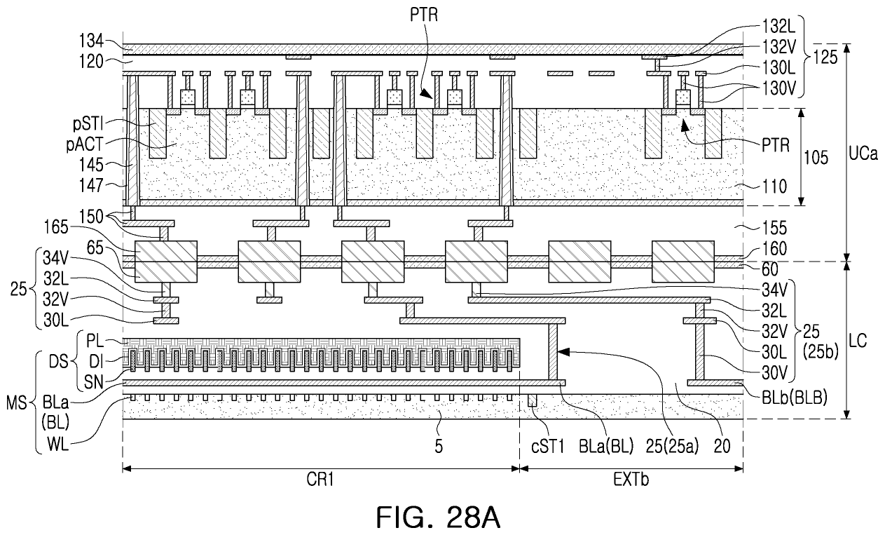

Referring to FIGS. 24, 27A, and 27B, a preliminary upper semiconductor structure UCa including upper bonding pads 165 may be formed (S20). Forming the preliminary upper semiconductor structure Uca may include forming a lower protective insulating layer 140, forming through-vias 145 and insulating spacers 147, forming an intermediate insulating structure 155 and intermediate connection structures 150, and forming an upper bonding insulating layer 160 and upper bonding pads 165.

The lower protective insulating layer 140 may be formed on the back surface of the upper semiconductor substrate 110. Accordingly, the upper base 105 as illustrated in FIGS. 7A and 7B may be formed.

Forming the through-vias 145 and the insulating spacers 147 may include forming through-holes that pass through the upper base 105 and extend downward to expose portions of the first upper interconnection structures 125, forming the insulating spacers 147 on side surfaces of the through holes, and forming the through-vias 145 in the through holes. The intermediate connection structures 150 may be formed to electrically connect the through-vias 145 and the upper bonding pads 165. The upper bonding insulating layer 160 and the upper bonding pads 165 may be formed to have coplanar upper surfaces.

Referring to FIGS. 24, 28A, and 28B, according to one or more example embodiments, a bonding process may be performed to bond the lower bonding pads 65 and the upper bonding pads 165 (S30). During the bonding process, the lower bonding insulating layer 60 and the upper bonding insulating layer 160 may be bonded. Accordingly, the lower chip structure (LC of FIGS. 25A and 25B) and the preliminary upper chip structure (UCa of FIGS. 27A and 27B) may be bonded.

Referring again to FIGS. 7A, 7B, and 8, an upper interconnection structure 175 may be formed (S40). The upper interconnection structure 175 may be formed on the first upper insulating structure 120. Before forming the upper interconnection structure 175, the protective insulating layer 134 may be removed. In one or more example embodiments, the process of removing the protective insulating layer 134 may be omitted. The upper interconnection structure 175 may be buried in the second upper insulating structure 170 formed on the first upper insulating structure 120.

Input/output pads 190 may be formed (S50). A capping insulating layer 185 may be formed on the second upper insulating structure 170. The capping insulating layer 185 may have an opening exposing upper surfaces of the input/output pads 190.

As set forth above, according to one or more example embodiments, a semiconductor device including a lower semiconductor chip including a memory structure and an upper semiconductor chip including a peripheral circuit may be provided. Accordingly, the degree of integration of semiconductor devices may be increased.

In addition, because an optimal routing structure for electrically connecting the lower semiconductor chip and the upper semiconductor chip may be provided, a semiconductor device having improved electrical characteristics may be provided.

While example embodiments have been particularly illustrated and described above, it will be apparent to those skilled in the art that modifications and variations in form and details may be made therein without departing from the scope of the following claims.

What is claimed is:

1. A semiconductor device comprising:
a lower chip structure; and
an upper chip structure on the lower chip structure,
wherein the lower chip structure comprises:
a memory structure;
a lower interconnection structure electrically connected to the memory structure; and
a lower bonding pad electrically connected to the lower interconnection structure, and
wherein the upper chip structure comprises:
an upper base;
a peripheral transistor on the upper base;
a first upper interconnection structure on the upper base and electrically connected to the peripheral transistor;
a through-via penetrating through the upper base and electrically connected to the first upper interconnection structure;
an upper bonding pad below the upper base and bonded to the lower bonding pad; and
an intermediate connection structure between the upper base and the lower chip structure and electrically connecting the upper bonding pad and the through-via.

2. The semiconductor device of claim 1, wherein the lower interconnection structure comprises:
at least two lower interconnection lines provided at different levels between the memory structure and the lower bonding pad;
at least two first lower plugs below the at least two lower interconnection lines, respectively; and
a second lower plug between an uppermost lower interconnection line, from among the at least two lower interconnection lines, and the lower bonding pad.

3. The semiconductor device of claim 2, wherein the intermediate connection structure comprises:
at least one intermediate interconnection line;
a first intermediate plug connecting the at least one intermediate interconnection line and the upper bonding pad; and
a second intermediate plug connecting the at least one intermediate interconnection line and the through-via.

4. The semiconductor device of claim 1, wherein the memory structure vertically overlaps the lower bonding pad, the upper bonding pad, the intermediate connection structure, the through-via, and the peripheral transistor.

5. The semiconductor device of claim 1, wherein the upper base comprises:
an upper semiconductor substrate;
a back protective insulating layer below the upper semiconductor substrate;
an upper active region on the upper semiconductor substrate; and
an upper isolation region on a side surface of the upper active region and in the upper semiconductor substrate,
wherein the peripheral transistor comprises:
a peripheral gate on the upper active region; and
peripheral source/drains in the upper active region on sides of the peripheral gate.

6. The semiconductor device of claim 1, wherein the memory structure comprises:
a cell transistor comprising:
a first source/drain;
a second source/drain; and
a cell gate electrode,
a bit line electrically connected to the first source/drain; and
a data storage structure electrically connected to the second source/drain.

7. The semiconductor device of claim 6, wherein the bit line extends outside the memory structure and comprises a bit line contact area outside the memory structure,
wherein the lower interconnection structure comprises:
at least two lower interconnection lines at a level higher than a level of the data storage structure and on different levels from each other;
at least one first lower plug electrically connecting the at least two lower interconnection lines;
a second lower plug electrically connecting a lowermost lower interconnection line from among the at least two lower interconnection lines and the bit line contact area of the bit line; and
a third lower plug electrically connecting an uppermost lower interconnection line, from among the at least two lower interconnection lines, and the lower bonding pad,
wherein the second lower plug does not vertically overlap with the data storage structure, and
wherein at least one of the at least two lower interconnection lines comprises:
a first region that does not vertically overlap with the data storage structure; and
a second region that vertically overlaps the data storage structure.

8. The semiconductor device of claim 1, wherein the through-via comprises:
a conductive pillar; and
a barrier layer covering side and upper surfaces of the conductive pillar, and
wherein a lower surface of the conductive pillar is connected to the intermediate connection structure.

9. The semiconductor device of claim 1, wherein the through-via comprises a conductive pillar and a barrier layer covering side and lower surfaces of the conductive pillar, and
wherein an upper surface of the conductive pillar is connected to the first upper interconnection structure.

10. The semiconductor device of claim 1, wherein the upper chip structure further comprises:
a second upper interconnection structure at a level higher than a level of the first upper interconnection structure; and
an input/output pad at a level higher than the level of the second upper interconnection structure,
wherein the first upper interconnection structure comprises at least one first upper interconnection line, and
wherein the second upper interconnection structure comprises at least one second upper interconnection line.

11. The semiconductor device of claim 10, wherein a thickness of the at least one second upper interconnection line is greater than a thickness of the at least one first upper interconnection line.

12. A semiconductor device comprising:
a lower chip structure comprising:
a first memory area;
a second memory area; and
an extension area between the first memory area and the second memory area;
and an upper chip structure on the lower chip structure,
wherein the lower chip structure further comprises:
bit lines in the first memory area and extending into the extension area; and
complementary bit lines in the second memory area and extending into the extension area,
wherein the upper chip structure comprises:
an upper base;
a sense amplifier array region comprising sense amplifier regions on the upper base; and
through-vias penetrating through the upper base,
wherein the sense amplifier array region vertically overlaps the first memory area,
wherein a first sense amplifier region, from among the sense amplifier regions, is electrically connected to a first bit line of the bit lines and to a first complementary bit line from among the complementary bit lines,
wherein the first sense amplifier region comprises:
a first connection region;
a second connection region; and
a first sense amplifier, and
wherein the through-vias comprise:
a first routing through-via below the first connection region and penetrating through the upper base; and
a second routing through-via below the second connection region and penetrating through the upper base.

13. The semiconductor device of claim 12, wherein the lower chip structure further comprises:
lower routing interconnection structures; and
lower routing bonding pads,
wherein the upper chip structure further comprises upper routing bonding pads below the upper base and bonded to the lower routing bonding pads,
wherein the lower routing interconnection structures comprise:
a first lower routing interconnection structure electrically connected to the first bit line; and
a second lower routing interconnection structure electrically connected to the first complementary bit line,
wherein the lower routing bonding pads comprise:
a first lower routing bonding pad electrically connected to the first lower routing interconnection structure; and
a second lower routing bonding pad electrically connected to the second lower routing interconnection structure, and
wherein the upper routing bonding pads comprise:
a first upper routing bonding pad bonded to the first lower routing bonding pad; and
a second upper routing bonding pad bonded to the second lower routing bonding pad.

14. The semiconductor device of claim 13, wherein each of the first lower routing interconnection structure and the second lower routing interconnection structure comprises: at least two lower interconnection lines at different levels;
at least two first lower plugs below the at least two lower interconnection lines, respectively; and
a second lower plug between an uppermost lower interconnection line, from among the at least two lower interconnection lines, and the first lower routing bonding pad,
wherein the second lower plug of the first lower routing interconnection structure is connected to the first lower routing bonding pad, and
wherein the second lower plug of the second lower routing interconnection structure is connected to the second lower routing bonding pad.

15. The semiconductor device of claim 13, wherein the upper chip structure comprises:
a first intermediate routing connection structure electrically below the upper base and connecting the first routing through-via and the first upper routing bonding pad; and
a second intermediate routing connection structure below the upper base and electrically connecting the second routing through-via and the second upper routing bonding pad.

16. The semiconductor device of claim 15, wherein each of the first intermediate routing connection structure and the second intermediate routing connection structure comprises:
at least one intermediate interconnection line;
a first intermediate plug below the at least one intermediate interconnection line; and
a second intermediate plug on the at least one intermediate interconnection line.

17. The semiconductor device of claim 15, wherein the first sense amplifier comprises:
peripheral transistors on the upper base; and
upper routing interconnection structures on the upper base and electrically connected to the peripheral transistors,
wherein the first routing through-via electrically connects the upper routing interconnection structures and the first intermediate routing connection structure in the first connection region, and
wherein the second routing through-via electrically connects the upper routing interconnection structures and the second intermediate routing connection structure in the second connection region.

18. The semiconductor device of claim 16, wherein a central vertical axis of the first routing through-via and a central vertical axis of the first upper routing bonding pad are not vertically aligned.

19. A semiconductor device comprising:
a lower chip structure comprising:
a first memory area;
a second memory area; and
an extension area between the first memory area and the second memory area; and
an upper chip structure on the lower chip structure,
wherein the lower chip structure comprises:
bit lines in the first memory area and extending into the extension area;
complementary bit lines in the second memory area and extending into the extension area;
a lower routing bonding pad array region on the first memory area, and comprising first lower routing bonding pads and second lower routing bonding pads;
first lower routing interconnection structures electrically connecting the bit lines and the first lower routing bonding pads; and
second lower routing interconnection structures electrically connecting the complementary bit lines and the second lower routing bonding pads,
wherein the upper chip structure comprises:
an upper base;
a sense amplifier array region on the upper base and comprising sense amplifier regions;
an upper routing bonding pad array region below the upper base, and comprising first upper routing bonding pads and second upper routing bonding pads;
routing through-vias penetrating through the upper base, and comprising first routing through-vias and second routing through-vias;
first intermediate routing connection structures between the upper base and the upper routing bonding pad array region, and electrically connecting the first routing through-vias and the first upper routing bonding pads; and
second intermediate routing connection structures between the upper base and the upper routing bonding pad array region, and electrically connecting the second routing through-vias and the second upper routing bonding pads,
wherein the first lower routing bonding pads and the second lower routing bonding pads are bonded to the first upper routing bonding pads and the second upper routing bonding pads,
wherein the sense amplifier array region, the routing through-vias, the upper routing bonding pad array region, and the lower routing bonding pad array region overlap the first memory area vertically, and
wherein a first sense amplifier region, from among the sense amplifier regions, is electrically connected to a first bit line, from among the bit lines, and a first upper bit line, from among the complementary bit lines.

20. The semiconductor device of claim 19, wherein the first sense amplifier region comprises:
a first connection region;
a second connection region; and
a first sense amplifier between the first connection region and the second connection region,
wherein the first routing through-vias penetrate the upper base and are below the first connection region, and
wherein the second routing through-vias penetrate the upper base and are below the second connection region.
